(19) United States
(12) Patent Application Publication
(10) Pub. No.: US 2017/0062690 A1
(43) Pub. Date: Mar. 2, 2017

(54) THERMOELECTRIC GENERATING UNIT AND METHODS OF MAKING AND USING SAME

(71) Applicant: Alphabet Energy, Inc., Hayward, CA (US)

(72) Inventors: Adam Lorimer, Walnut Creek, CA (US); Christopher Hannemann, Berkeley, CA (US); Douglas Crane, Richmond, CA (US); Ad de Pijper, Walnut Creek, CA (US); Sasi Bhushan Beera, Fremont, CA (US); Jordan Chase, Oakland, CA (US); Mario Aguirre, Livermore, CA (US); Daniel Freeman, San Jose, CA (US)

(21) Appl. No.: 14/872,681

(22) Filed: Oct. 1, 2015

Related U.S. Application Data
(60) Provisional application No. 62/059,084, filed on Oct. 2, 2014.

(51) Int. Cl. H01L 35/32; H01L 35/30; H01L 35/34; H01L 35/02

(52) U.S. Cl. CPC H01L 35/32; H01L 35/02; H01L 35/30; H01L 35/34

(57) ABSTRACT

A thermoelectric generating unit includes a hot-side heat exchanger (HHX) including one or more discrete channels and substantially flat first and second cold-side plates. A first plurality of thermoelectric devices are between the first cold-side plate and a first side of the HHX; and a second plurality of thermoelectric devices can be between the second cold-side plate and a second side of the HHX. Fasteners can extend between the first and second cold-side plates at locations outside of the HHX channel(s). The fasteners can be disposed within gaps between the thermoelectric devices of the first plurality and within gaps between the thermoelectric devices of the second plurality. The fasteners can compress the first plurality of thermoelectric devices between the first cold-side plate and the first side of the HHX and can compress the second plurality of thermoelectric devices between the second cold-side plate and the second side of the HHX.

### CROSS-REFERENCE TO RELATED APPLICATIONS

This application claims the benefit of U.S. Provisional Patent Application No. 62/059,084, filed on Oct. 2, 2014 and entitled “THERMOELECTRIC GENERATING UNIT AND METHODS OF MAKING AND USING SAME,” the entire contents of which are incorporated by reference herein.

This application is related to U.S. Provisional Patent Application No. 62/059,092, filed on Oct. 2, 2014 and entitled “THERMOELECTRIC GENERATORS FOR RECOVERING WASTE HEAT FROM ENGINE EXHAUST, AND METHODS OF MAKING AND USING THE SAME,” the entire contents of which are incorporated by reference herein.

This application also is related to U.S. patent application No. (TBA), filed on even date herewith and entitled “THERMOELECTRIC GENERATORS FOR RECOVERING WASTE HEAT FROM ENGINE EXHAUST, AND METHODS OF MAKING AND USING THE SAME,” the entire contents of which are incorporated by reference herein.

### FIELD

This present application is directed to thermoelectric generating units. It would be recognized that the invention has a much broader range of applicability.

### BACKGROUND

Thermoelectric (TE) devices are often packaged using a plurality of thermoelectric legs arranged in multiple serial chain configurations on a base structure. Each of the plurality of thermoelectric legs can include either p-type or n-type thermoelectric material, which can be characterized by high electrical conductivity and relatively high thermal resistivity. One or more p-type TE legs can be pairwise-coupled to one or more n-type TE legs via a conductor from each direction in a serial chain or electrically in series-thermally in parallel or electrically in parallel-thermally in parallel configuration, one conductor being coupled at one end region of the TE leg and another conductor being coupled at another end region of the TE leg. When a bias voltage is applied across the top/bottom regions of the thermoelectric device using the two conductors as two electrodes, a temperature difference is generated so that the thermoelectric device can be used as a refrigeration (e.g., Peltier) device. When the thermoelectric device is subjected to a thermal junction with conductors at first end regions of the TE legs being attached to a cold side of the junction and conductors at second end regions of the TE legs being in contact with a hot side of the junction, the thermoelectric device is able to generate electrical voltage across the junction as an energy conversion (e.g., Seebeck) device.

The energy conversion efficiency of thermoelectric devices can be measured by a so-called thermal power density or “thermoelectric figure of merit” ZT, where ZT is equal to TS² σ/k where T is the temperature, S the Seebeck coefficient, σ the electrical conductivity, and k the thermal conductivity of the thermoelectric material. In order to drive up the value of ZT of thermoelectric devices utilizing the Seebeck effect, searching for high performance thermoelectric materials and developing low cost manufacturing processes are major concerns. However, new material combinations and new environmental requirements reveal the needs of improved techniques for packaging thermoelectric devices.

### SUMMARY

This present application is directed to thermoelectric generating units. It would be recognized that the invention has a much broader range of applicability.

Under one aspect, a thermoelectric generating unit includes a hot-side heat exchanger including a first side, a second side, and one or more discrete channels; a substantially flat first cold-side plate; and a substantially flat second cold-side plate. The thermoelectric generating unit further can include a first plurality of thermoelectric devices arranged between the first cold-side plate and the first side of the hot-side heat exchanger; and a second plurality of thermoelectric devices arranged between the second cold-side plate and the second side of the hot-side heat exchanger. The thermoelectric generating unit further can include a plurality of fasteners extending between the first cold-side plate and the second cold-side plate at respective locations outside of the one or more discrete channels of the hot-side heat exchanger. The fasteners can be disposed within gaps between the thermoelectric devices of the first plurality and within gaps between the thermoelectric devices of the second plurality. The fasteners can compress the first plurality of thermoelectric devices between the first cold-side plate and the first side of the hot-side heat exchanger and compressing the second plurality of thermoelectric devices between the second cold-side plate and the second side of the hot-side heat exchanger.

In some embodiments, a first subset of the first plurality of thermoelectric devices is centrally disposed and a second subset of the first plurality of thermoelectric devices is peripherally disposed. A first subset of the plurality of fasteners can apply a first force to the first subset of the first plurality of thermoelectric devices. A second subset of the plurality of fasteners can apply a second force to the second subset of the first plurality of thermoelectric devices. The first force can be greater than the second force. For example, the first force is at least 1.5 times the second force. In some embodiments, a third subset of the first plurality of thermoelectric devices is disposed between the first subset of the first plurality of thermoelectric devices and the third subset of the first plurality of thermoelectric devices. A third subset of the plurality of fasteners can apply a third force to the third subset of the first plurality of thermoelectric devices. The third force can be less than the first force and greater than the second force. In some embodiments, the first force is about 1.5 times the third force, and the first force is about 3 times the second force. In some embodiments, the first force can be about 11-13 kN, the third force is about 7-9 kN, and the second force is about 3-5 kN.

In some embodiments, each fastener includes a bolt or screw; and a spring, a Belleville washer, or a spring washer disposed along the bolt or screw. In some embodiments, a first subset of the plurality of fasteners includes a greater number of springs, Belleville washers, or spring washers disposed along the bolts or screws of that subset than does a second subset of the plurality of fasteners.

In some embodiments, the first plurality of thermoelectric devices is arranged in columns and rows between the first cold-side plate and the first side of the hot-side heat exchanger, the fasteners respectively being disposed within gaps between the columns and rows. Some embodiments include four fasteners for every four thermoelectric devices of the first plurality of thermoelectric devices and for every four thermoelectric devices of the second plurality of thermoelectric devices.

In some embodiments, the hot-side heat exchanger further includes fins disposed within each of the one or more discrete channels. In some embodiments, the fins include stainless steel, nickel plated copper, or stainless steel clad copper. In some embodiments, a density of the fins within each of the one or more discrete channels is at least 12 fins per inch.

In some embodiments, the hot-side heat exchanger includes at least one threaded rod configured to sealingly couple the hot-side heat exchanger to a pipe flange.

In some embodiments, the first cold-side plate further includes pin fins, straight fins, or offset fins. In some embodiments, the pin fins are arranged in an in-line arrangement or in a staggered arrangement.

In some embodiments, the first plurality of thermoelectric devices is disposed on a circuit board.

In some embodiments, the first plurality of thermoelectric devices include a thermoelectric material, the thermoelectric material being selected from the group consisting of: tetrahedrite, magnesium silicide, magnesium silicide stannide, silicon, silicon nanowire, bismuth telluride, skutterudite, lead telluride, TAGS (tellurium-antimony-germanium-silver), zinc antimonide, silicon germanium, and a half-Heusler compound.

In some embodiments, at least one of the first cold-side plate and the second cold-side plate includes a high efficiency cold-side heat exchanger; and the hot-side heat exchanger includes a high efficiency hot-side heat exchanger.

In some embodiments, the first cold-side plate includes an inlet for coolant inflow and an outlet for coolant outflow, wherein the inlet and outlet are on the same side of the first cold-side plate as one another.

Some embodiments include at least one of the following: a kapton film disposed between the first side of the hot-side heat exchanger and at least one thermoelectric device of the first plurality of thermoelectric devices; a kapton film disposed between the first cold-side plate and at least one thermoelectric device of the first plurality of thermoelectric devices; a mica sheet disposed between the first side of the hot-side heat exchanger and at least one thermoelectric device of the first plurality of thermoelectric devices; a graphite sheet disposed between the first side of the hot-side heat exchanger and at least one thermoelectric device of the first plurality of thermoelectric devices; a gap pad disposed between the first cold-side plate and at least one thermoelectric device of the first plurality of thermoelectric devices; and an anodized layer disposed between the first cold-side plate and at least one thermoelectric device of the first plurality of thermoelectric devices.

Under another aspect, a method of assembling a thermoelectric generating unit includes providing a hot-side heat exchanger including a first side, a second side, and one or more discrete channels; providing a substantially flat first cold-side plate; and providing a substantially flat second cold-side plate. The method can include arranging a first plurality of thermoelectric devices between the first cold-side plate and the first side of the hot-side heat exchanger and arranging a second plurality of thermoelectric arranged between the second cold-side plate and the second side of the hot-side heat exchanger. The method also can include disposing a plurality of fasteners extending between the first cold-side plate and the second cold-side plate at respective locations outside of the one or more discrete channels of the hot-side heat exchanger and within gaps between the thermoelectric devices of the first plurality and within gaps between the thermoelectric devices of the second plurality. The method also can include compressing by the fasteners the first plurality of thermoelectric devices between the first cold-side plate and the first side of the hot-side heat exchanger and the second plurality of thermoelectric devices between the second cold-side plate and the second side of the hot-side heat exchanger.

In some embodiments, the method further can include centrally disposing a first subset of the first plurality of thermoelectric devices; peripherally disposing a second subset of the first plurality of thermoelectric devices; applying a first force to the first subset of the first plurality of thermoelectric devices with a first subset of the plurality of fasteners; and applying a second force to the second subset of the first plurality of thermoelectric devices with a second subset of the plurality of fasteners. The first force can be greater than the second force. For example, the first force can be at least 1.5 times the second force. In some embodiments, the method further can include disposing a third subset of the first plurality of thermoelectric devices is between the first subset of the first plurality of thermoelectric devices and the third subset of the first plurality of thermoelectric devices; and applying a third force to the third subset of the first plurality of thermoelectric devices with a third subset of the plurality of fasteners. The third force can be less than the first force and greater than the second force. In some embodiments, the first force is about 1.5 times the third force, and the first force is about 3 times the second force. In some embodiments, the first force is about 11-13 kN, the third force is about 7-9 kN, and the second force is about 3-5 kN.

In some embodiments, each fastener includes a bolt or screw; and a spring, a Belleville washer, or a spring washer disposed along the bolt or screw. In some embodiments, a first subset of the plurality of fasteners includes a greater number of springs, Belleville washers, or spring washers disposed along the bolts or screws of that subset than does a second subset of the plurality of fasteners.

In some embodiments, the method further includes arranging the first plurality of thermoelectric devices in columns and rows between the first cold-side plate and the first side of the hot-side heat exchanger; and respectively disposing the fasteners within gaps between the columns and rows. Some embodiments include disposing four fasteners for every four thermoelectric devices.

In some embodiments, the hot-side heat exchanger further includes fins disposed within each of the one or more discrete channels. In some embodiments, the fins include stainless steel, nickel plated copper, or stainless steel clad copper. In some embodiments, a density of the fins within each of the one or more discrete channels is at least 12 fins per inch.

In some embodiments, the hot-side heat exchanger includes at least one threaded rod, and the method further includes sealingly coupling the hot-side heat exchanger to a pipe flange via the at least one threaded rod.

In some embodiments, the first cold-side plate further includes pin fins, straight fins, or offset fins. In some embodiments, the pin fins are arranged in an in-line arrangement or in a staggered arrangement, or include brazed offset pin fins.

In some embodiments, the method further includes disposing the first plurality of thermoelectric devices on a circuit board.

In some embodiments, the first plurality of thermoelectric devices include a thermoelectric material, the thermoelectric material being selected from the group consisting of: tetrahedrite, magnesium silicide, magnesium silicide stannide, silicon, silicon nanowire, bismuth telluride, skutterudite, lead telluride, TAGS (tellurium-antimony-germanium-silver), zinc antimonide, silicon germanium, and a half-Heusler compound.

In some embodiments, at least one of the first cold-side plate and the second cold-side plate includes a high efficiency cold-side heat exchanger; and the hot-side heat exchanger includes a high efficiency hot-side heat exchanger.

In some embodiments, the first cold-side plate includes an inlet for coolant inflow and an outlet for coolant outflow, wherein the inlet and outlet are on the same side of the first cold-side plate as one another.

In some embodiments, the method includes at least one of the following: disposing a kapton film between the first side of the hot-side heat exchanger and at least one thermoelectric device of the first plurality of thermoelectric devices; disposing a kapton film between the first cold-side plate and at least one thermoelectric device of the first plurality of thermoelectric devices; disposing a mica sheet between the first side of the hot-side heat exchanger and at least one thermoelectric device of the first plurality of thermoelectric devices; disposing a graphite sheet between the first side of the hot-side heat exchanger and at least one thermoelectric device of the first plurality of thermoelectric devices; disposing a gap pad between the first cold-side plate and at least one thermoelectric device of the first plurality of thermoelectric devices; and disposing an anodized layer between the first cold-side plate and at least one thermoelectric device of the first plurality of thermoelectric devices.

### BRIEF DESCRIPTION OF DRAWINGS

FIGS. 1A-1G schematically illustrate views of an exemplary thermoelectric generating unit, according to some embodiments.

FIGS. 2A-2C schematically illustrate views of an exemplary thermoelectric assembly for use in a thermoelectric generating unit such as illustrated in FIGS. 1A-1G, according to some embodiments.

FIGS. 3A-3C schematically illustrate exemplary arrangements of fasteners for use in a thermoelectric generating unit such as illustrated in FIGS. 1A-1G, according to some embodiments.

FIG. 4A schematically illustrates one nonlimiting example of an arrangement of fasteners for use in a thermoelectric generating unit such as illustrated in FIGS. 1A-1G, according to some embodiments.

FIG. 4B schematically illustrates one nonlimiting example of a distribution of pressures that can be obtained using the arrangement of fasteners illustrated in FIG. 4A.

FIG. 5 illustrates a plot of exemplary power output as a function of exhaust flow for a thermoelectric generating unit such as illustrated in FIGS. 1A-1G, according to some embodiments.

FIG. 6 illustrates a plot of exemplary pressure drop as a function of exhaust flow for a thermoelectric generating unit such as illustrated in FIGS. 1A-1G, according to some embodiments.

FIG. 7 schematically illustrates steps in an exemplary method of preparing a thermoelectric generating unit, according to some embodiments.

### DETAILED DESCRIPTION

This present application is directed to thermoelectric generating units. It would be recognized that the invention has a much broader range of applicability.

For example, embodiments of the present thermoelectric generating units can include a plurality of thermoelectric devices that are provided in a sandwich-type arrangement that includes a central hot-side heat exchanger that can be configured so as to receive a fluid carrying waste heat, e.g., exhaust from an engine, and two cold-side plates arranged on either side of the hot-side heat exchanger. Some of the thermoelectric devices can be disposed between one side of the hot-side heat exchanger and one of the cold-side plates, and some of the thermoelectric devices can be disposed between the other side of the hot-side heat exchanger and the other cold-side plate. So as to provide for sufficient thermal contact between the thermoelectric devices, the hot-side heat exchanger, and the respective cold-side plates throughout a range of operating temperatures while inhibiting leakage of the fluid carrying waste heat, a plurality of fasteners can be distributed across and can compress the sandwich-type arrangement. For example, the hot-side heat exchanger can include one or more discrete channels, e.g., multiple discrete channels, through which the fluid carrying waste heat can flow, and the fasteners can be arranged outside of the one or more discrete channels, e.g., within gaps between the channels, rather than being disposed through one of the channels, so as to inhibit potential leakage of the fluid out of the hot-side heat exchanger within the thermoelectric generating unit. Additionally, or alternatively, the fasteners can be disposed within gaps between the thermoelectric devices. The cold-side plates can be substantially flat, so that the pressure imposed by the fasteners onto the thermoelectric devices can be relatively even across the thermoelectric generating unit at operating temperature.

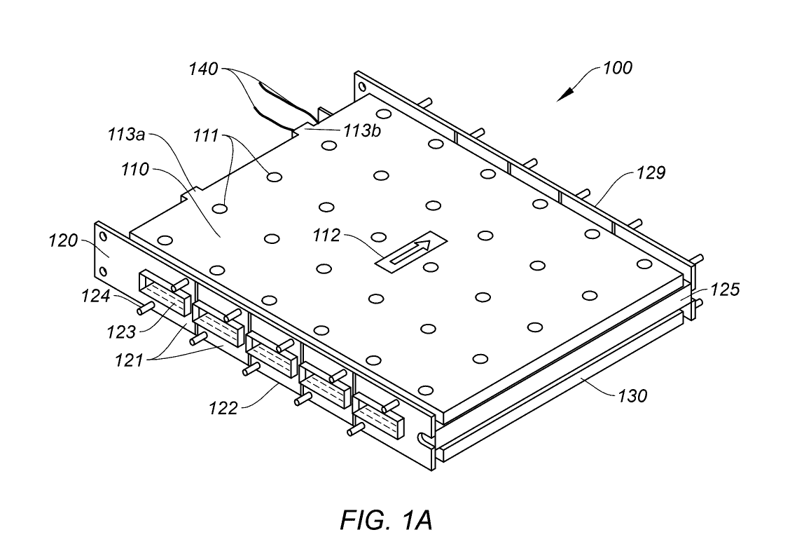

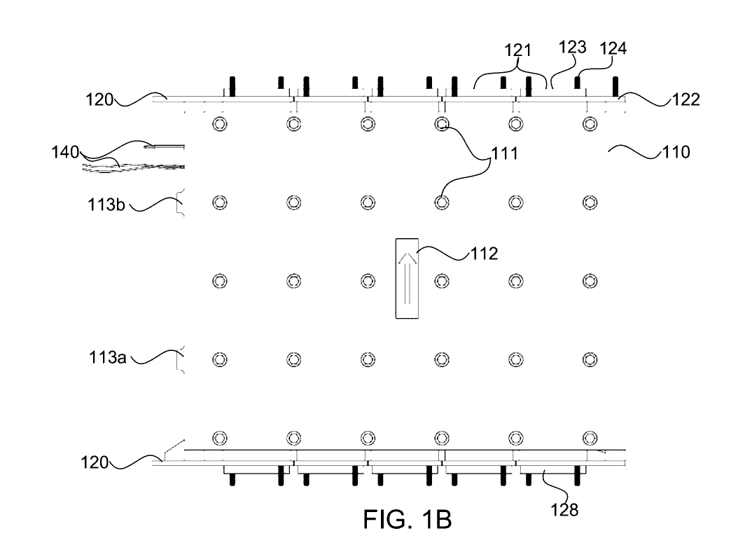

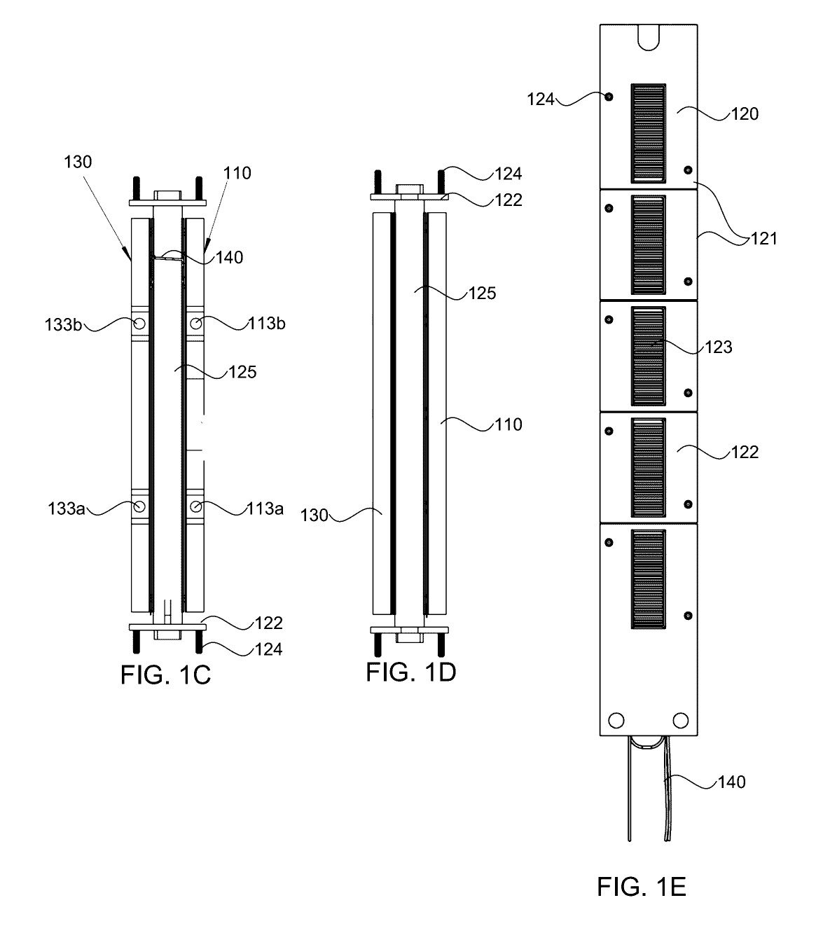

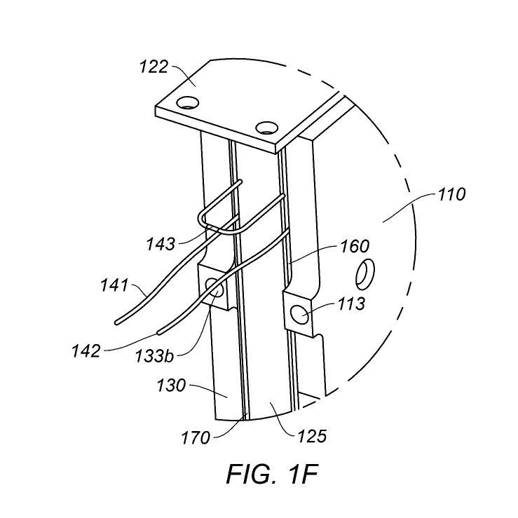

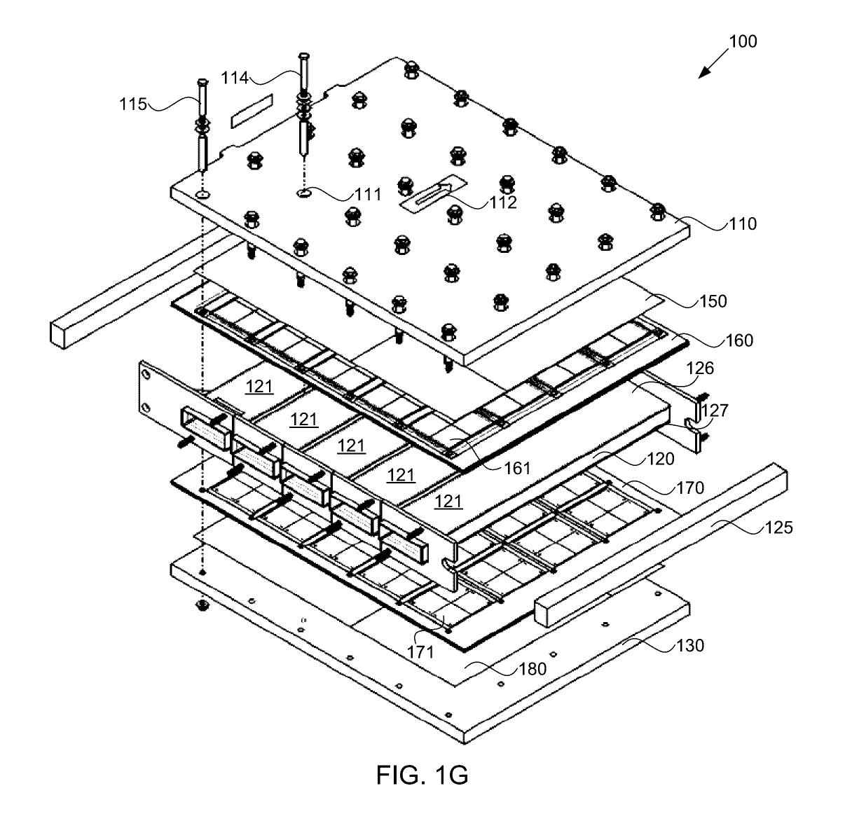

FIGS. 1A-1G schematically illustrate views of an exemplary thermoelectric generating unit (TGU), according to some embodiments. The non-limiting embodiment of TGU 100 illustrated in FIGS. 1A-1G includes first cold-side plate 110, hot side heat exchanger 120, second cold-side plate 130, first thermoelectric assembly 160, second thermoelectric assembly 170, and a plurality of fasteners 111. As can be seen in FIG. 1C, first thermoelectric assembly 160 can be disposed between first cold-side plate 110 and first side 126 of hot-side heat exchanger 120, and second thermoelectric assembly 170 can be disposed between second cold-side plate 120 and second side 127 of hot-side heat exchanger 120. Fasteners 111 can be disposed through holes that are defined through first cold-side plate 110, hot side heat exchanger 120, second cold-side plate 130, first thermoelectric assembly 160, and second thermoelectric assembly 170, and can provide a suitable distribution of forces and pressures over the TGU so as to maintain satisfactory thermal contact between components of the TGU under a variety of operating conditions that can cause different thermal expansions of such components.

In some embodiments, hot-side heat exchanger 120 includes first side 126, second side 127, and one or more discrete channels, e.g., a plurality of discrete channels 121. Each of the one or more discrete channels 121 can be configured so as to receive fluid carrying waste heat, e.g., exhaust from an engine. For example, each of the one or more discrete channels 121 can include a fluidic inlet 123 and a fluidic outlet 128 and a lumen that fluidically couples inlet 123 and outlet 128 to one another. The lumen can be configured so as to extract heat from a fluid passing therethrough, e.g., in the direction denoted by arrow 112 illustrated in FIGS. 1A, 1B, and 1G. For example, in some embodiments, hot-side heat exchanger 120 further can include fins disposed within the lumen of each of the one or more discrete channels 121. The fins can include any suitable composition. Illustratively, such fins can include, e.g., stainless steel, nickel plated copper, or stainless steel clad copper. Any suitable arrangement, number, and density of fins can be provided so as to facilitate extraction of heat from the fluid passing through the one or more discrete channels 121. For example, in some embodiments, a density of the fins within each of the one or more discrete channels is at least 12 fins per inch. In one illustrative embodiment, the hot-side heat exchanger includes a high efficiency hot-side heat exchanger. As used herein, “high efficiency hot-side heat exchanger” is intended to mean a hot-side heat exchanger characterized by a thermal resistance of less than about 0.0015 m²K/W, e.g., a thermal resistance of less than about 0.00025 m²K/W.

Additionally, or alternatively, hot-side heat exchanger 121 optionally can include at least one threaded rod 124 configured to sealingly couple the hot-side heat exchanger to a pipe flange or other suitable source of a fluid that carries waste heat. For example, in the embodiment illustrated in FIGS. 1A-1G, each of the one or more discrete channels 121 of heat exchanger 120 can include four threaded rods, two for coupling front plate 122 of hot-side heat exchanger 120 to a first region of a pipe flange, and two for coupling back plate 129 of hot-side heat exchanger to a second region of the pipe flange. It should be understood that any suitable type, number, and arrangement of fasteners can be used so as to couple hot side heat exchanger 121 to a source of a fluid that carries waste heat.

In some embodiments, first cold-side plate 110 and second cold-side plate 130 are substantially flat. By “substantially flat” it is meant that the cold-side plate includes first and second major surfaces that each are substantially planar and parallel to one another, e.g., are characterized by a flatness and planarity specification of about 0.010″ or less across the cold side plate. In some embodiments, first cold-side plate 110 and second cold-side plate 130 each are substantially flat over substantially the entire lateral surface of thermoelectric generating unit 110. In one non-limiting example, each of first cold-side plate 110 and second cold-side plate 130 can include a substantially flat slab of a thermally conductive material, such as a metal or a ceramic. Exemplary metals that can be suitable for use in one or both of first cold-side plate 110 and second cold-side plate 130 independently can be selected from the group consisting of aluminum, copper, molybdenum, tungsten, copper-molybdenum alloy, stainless steel, and nickel. Exemplary ceramics that can be suitable for use in one or both of first cold-side plate 110 and second cold-side plate 130 independently can be selected from the group consisting of silicon carbide, aluminum nitride, alumina, and silicon nitride. In one illustrative embodiment, one of first cold-side plate 110 and second cold-side plate 130 can include a metal, e.g., an exemplary metal listed above, and the other of first cold-side plate 130 and second cold-side plate 130 can include a ceramic, e.g., an exemplary ceramic listed above. In another illustrative embodiment, both first cold-side plate 110 and second cold-side plate 130 can include a metal, e.g., an exemplary metal listed above. In yet another illustrative embodiment, both first cold-side plate 110 and second cold-side plate 130 can include a ceramic, e.g., an exemplary ceramic listed above.

Each of the first cold-side plate 110 and second cold-side plate 130, e.g., substantially flat slabs, can include a plurality of apertures defined therethrough for respectively receiving fasteners 111. As one example, the apertures can extend through the entire thickness of each of the substantially flat slabs. As another example, the apertures can extend through only a portion of the thickness of one or both of the substantially flat slabs. In some embodiments, the apertures are arranged in a plurality of rows and a plurality of columns across the surface of each of the substantially flat slabs.

In some embodiments, one or both of substantially flat first cold-side plate 110 and substantially second cold-side plate 130 include one or more channels defined therein that are configured to receive a fluidic coolant, e.g., a liquid or gaseous coolant. One or both of first cold-side plate 110 and second cold-side plate 130 can include one or more inlets 113a or 113b for coolant inflow and one or more outlets 113b or 113a for coolant outflow. In one example, the inlet 113a or 113b and outlet 113b or 113a for first cold-side plate 110 are on the same side of the first cold-side plate as one another, and the inlet 133a or 133b and outlet 133b or 133a for second cold-side plate 130 are on the same side of the second cold-side plate as one another, e.g., so as to facilitate ease of installation and access to the ports.

Additionally, or alternatively, one or both of first cold-side plate 110 and second cold-side plate 130 further can include pin fins, straight fins, or offset fins. In some embodiments, the fins can be disposed inside of one or both of first cold-side plate 110 and second cold-side plate 130, e.g., can be disposed within channels respectively defined within one or both of first cold-side plate 110 and second cold-side plate 130. The fins can be used to provide extended surfaces or increased surface area to increase heat transfer. The fins can also change the hydraulic diameter and alter flow paths causing disruptions to the boundary layer, again increasing heat transfer. In some embodiments, the pin fins optionally can be arranged in an in-line arrangement or in a staggered arrangement. In one non-limiting example, at least one of first cold-side plate 110 and second cold-side plate 130 includes a high efficiency cold-side heat exchanger. As used herein, the term “high efficiency cold-side heat exchanger” is intended to mean a cold-side heat exchanger characterized by a thermal resistance of less than about 7.5e-10 m²K/W.

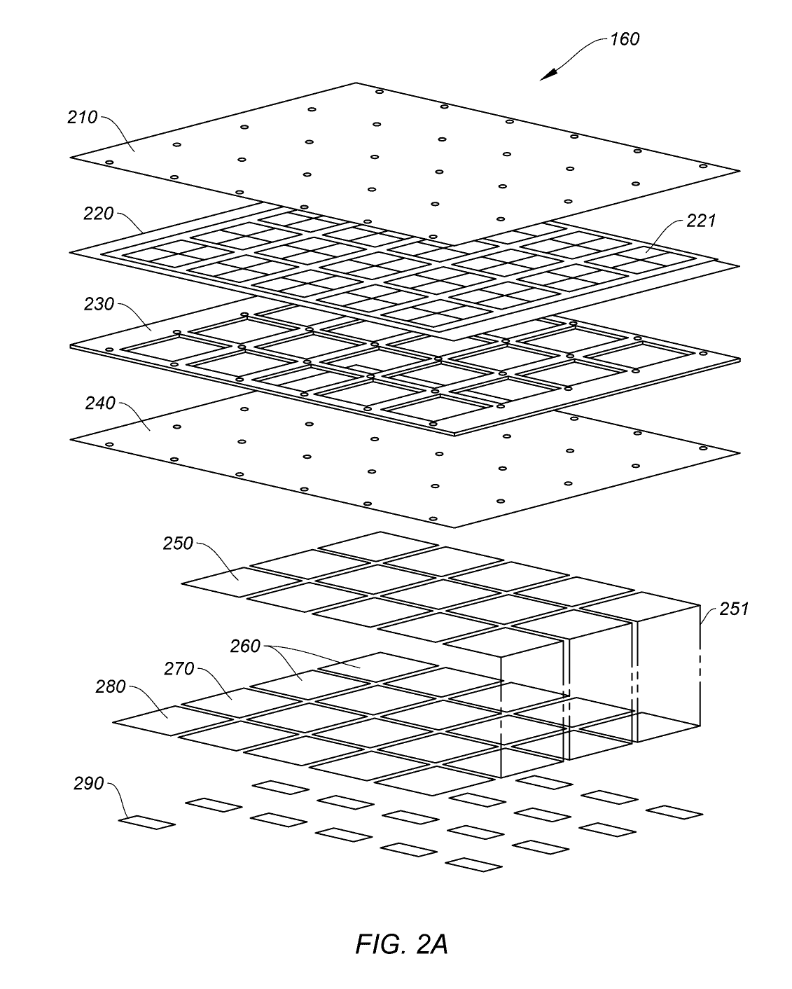

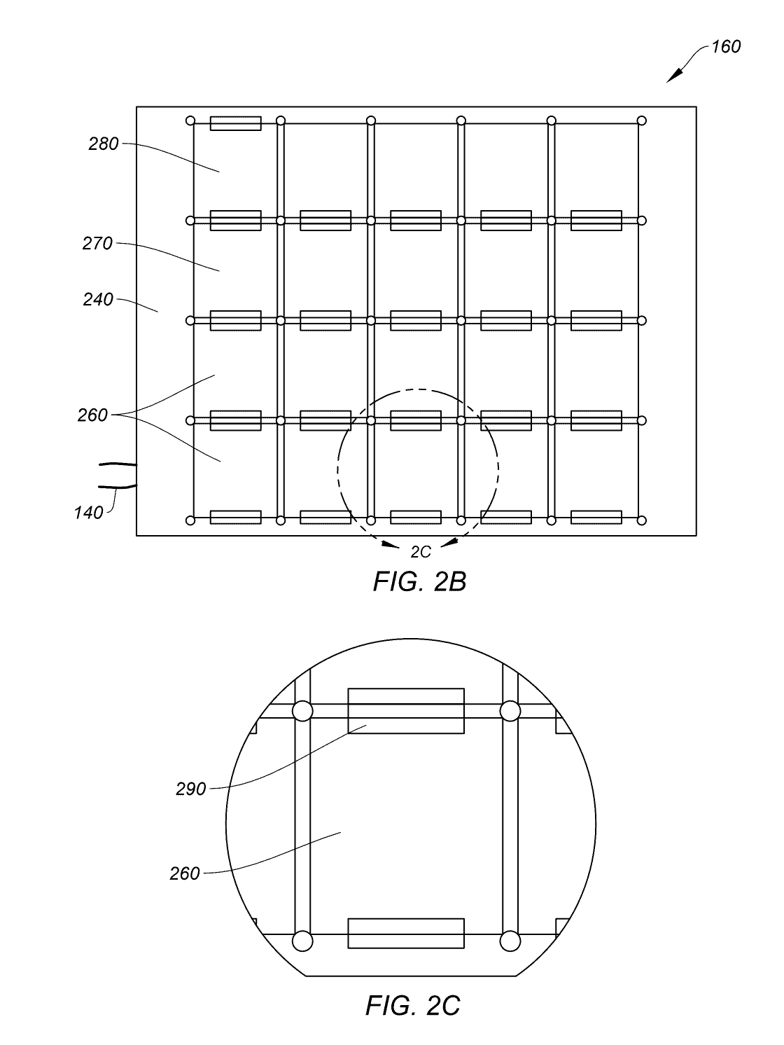

In the embodiment illustrated in FIGS. 1A-1G, thermoelectric generating unit further includes a first plurality of thermoelectric devices 161 arranged between first cold-side plate 110 and first side 126 of hot-side heat exchanger 120, and a second plurality of thermoelectric devices 171 arranged between second cold-side plate 130 and second side 127 of hot-side heat exchanger 120. As one example, first plurality of thermoelectric devices 161 can be provided as part of first thermoelectric assembly 160, and second plurality of thermoelectric devices 171 can be provided as part of second thermoelectric assembly 170. Exemplary embodiments of thermoelectric assemblies such as suitable for use in one or both of first thermoelectric assembly 160 and second thermoelectric assembly 170 are described below with reference to FIGS. 2A-2C. In embodiments such as described in greater detail below with reference to FIGS. 2A-2C, one or both of first plurality of thermoelectric devices 161 and second plurality of thermoelectric devices 171 can be disposed on a circuit board.

First plurality of thermoelectric devices 161 can be arranged in columns and rows between first cold-side plate 110 and first side 126 of hot-side heat exchanger 120, and fasteners 111 respectively can be disposed within gaps between the columns and rows, e.g., so that the fasteners need not be passed through any of the thermoelectric devices 161 of the first plurality. Additionally, or alternatively, second plurality of thermoelectric devices 171 can be arranged in columns and rows between second cold-side plate 130 and second side 127 of hot-side heat exchanger 120, and fasteners 111 respectively can be disposed within gaps between the columns and rows, e.g., so that the fasteners need not be passed through any of the thermoelectric devices 171 of the second plurality.

The thermoelectric devices 161, 171 of the first and second pluralities of thermoelectric devices can have any suitable configuration. For example, each of the thermoelectric devices 161, 171 can include one or more thermoelectric legs, e.g., can include one or more p-type thermoelectric legs and one or more n-type thermoelectric legs. Each of the thermoelectric legs can include a thermoelectric material disposed between first and second conductive materials. The p-type thermoelectric legs can include a different material, or the same material but with different doping, than do the n-type thermoelectric legs. For example, one or both of first plurality 161 and second plurality 171 of thermoelectric devices can include a thermoelectric material selected from the group consisting of: tetrahedrite, magnesium silicide, magnesium silicide stannide, silicon, silicon nanowire, bismuth telluride, skutterudite, lead telluride, TAGS (tellurium-antimony-germanium-silver), zinc antimonide, silicon germanium, a half-Heusler compound, or any other thermoelectric material known in the art or yet to be developed. Optionally, one or more of the p-type thermoelectric legs can be connected electrically in series and thermally in parallel with one or more of the n-type thermoelectric legs so as to generate an electrical current responsive to a temperature differential across the assembly. Any suitable number of thermoelectric legs can be provided within each thermoelectric device 161, 171. In non-limiting examples, each thermoelectric device can include 1 to 100 p-type thermoelectric legs and 1 to 100 n-type thermoelectric legs, or 10 to 80 p-type thermoelectric legs and 10 to 80 n-type thermoelectric legs, or 20 to 60 p-type thermoelectric legs and 20 to 60 n-type thermoelectric legs, e.g., 48 p-type thermoelectric legs and 48 n-type thermoelectric legs. The number of p-type thermoelectric legs in a thermoelectric device can be, but need not necessarily be, the same as the number of n-type thermoelectric legs in that thermoelectric device.

First plurality of thermoelectric devices 161 can be electrically connected so as to obtain current therefrom responsive to a temperature differential between hot-side heat exchanger 120 and first cold-side plate 110. Second plurality of thermoelectric devices 171 can be electrically connected so as to obtain current therefrom responsive to a temperature differential between hot-side heat exchanger 120 and second cold-side plate 130. In one nonlimiting embodiment, first plurality of thermoelectric devices 161 is connected electrically in serial with second plurality of thermoelectric devices 171 using conductor(s) 140. For example, the exemplary external connections illustrated in FIG. 1F include wiring 141, 142, and 143. Positive wiring 141 and negative wiring 142 respectively extend from first thermoelectric assembly 160 and second thermoelectric assembly 170. Series wiring 143 extends from both first thermoelectric assembly 160 and second thermoelectric assembly 170 so as to connect assemblies 160, 170 electrically in series with one another. The thermoelectric devices respectively of first thermoelectric assembly 160 and second thermoelectric assembly 170 are wired in a series-parallel configuration internally.

For further examples of thermoelectric legs, electrical connections, and thermoelectric devices that suitably can be used in the present thermoelectric generating units, see the following references, the entire contents of each of which are incorporated by reference herein: U.S. Pat. No. 8,736,011 entitled “Low thermal conductivity matrices with embedded nanostructures and methods thereof,” U.S. Pat. No. 9,051,175 entitled “Bulk nano-ribbon and/or nano-porous structures for thermoelectric devices and methods for making the same,” U.S. Pat. No. 9,065,017 entitled “Thermoelectric devices having reduced thermal stress and contact resistance, and methods of forming and using the same,” U.S. Pat. No. 9,082,930 entitled “Nanostructured thermoelectric elements and methods of making the same,” U.S. Patent Publication No. 2011/0114146 entitled “Uniwafer thermoelectric modules,” U.S. Patent Publication No. 2012/0152295 entitled “Arrays of filled nanostructures with protruding segments and methods thereof,” U.S. Patent Publication No. 2012/0247527 entitled “Electrode structures for arrays of nanostructures and methods thereof,” U.S. Patent Publication No. 2012/0295074, “Arrays of long nanostructures in semiconductor materials and methods thereof,” U.S. Patent Publication No. 2012/0319082 entitled “Low thermal conductivity matrices with embedded nanostructures and methods thereof,” U.S. Patent Publication No. 2013/0175654 entitled “Bulk nanohole structures for thermoelectric devices and methods for making the same,” U.S. Patent Publication No. 2013/0186445 entitled “Modular thermoelectric units for heat recovery systems and methods thereof,” U.S. Patent Publication No. 2014/0024163 entitled “Method and structure for thermoelectric unicouple assembly,” U.S. Patent Publication No. 2014/0116491 entitled “Bulk-size nanostructured materials and methods for making the same by sintering nanowires,” U.S. Patent Publication No. 2014/0182644 entitled “Structures and methods for multi-leg package thermoelectric devices,” U.S. Patent Publication No. 2014/0193982 entitled “Low thermal conductivity matrices with embedded nanostructures and methods thereof,” U.S. Patent Publication No. 2014/0360546 entitled “Silicon-based thermoelectric materials including isoelectronic impurities, thermoelectric devices based on such materials, and methods of making and using same,” U.S. Patent Publication No. 2015/0147842 entitled “Arrays of filled nanostructures with protruding segments and methods thereof,” U.S. Patent Publication No. 2015/0295074 entitled “Arrays of long nanostructures in semiconductor materials and methods thereof,” U.S. patent application Ser. No. 14/679,837 filed Apr. 6, 2015 and entitled “Flexible lead frame for multi-leg package assembly,” and U.S. patent application Ser. No. 14/682,471 filed Apr. 9, 2015 and entitled “Ultra-long silicon nanostructures, and methods of forming and transferring the same.”

Referring still to FIGS. 1A-1G, thermoelectric generating unit 100 further can include a plurality of fasteners 111 extending between first cold-side plate 110 and second cold-side plate 130 at respective locations outside of the one or more discrete channels 121, e.g., between discrete channels 121, of hot-side heat exchanger 120. Additionally, or alternatively, fasteners 111 can be disposed within gaps between the thermoelectric devices 161 of the first plurality and within gaps between the thermoelectric devices of the second plurality 171. Fasteners 111 can be configured so as to compress first plurality of thermoelectric devices 161 between first cold-side plate 110 and first side 126 of hot-side heat exchanger 120 and also can be configured so as to compress second plurality of thermoelectric devices 171 between second cold-side plate 130 and second side 127 of hot-side heat exchanger 120.

Any suitable number of fasteners 111 can be provided relative to the number of thermoelectric devices of first plurality of thermoelectric devices 161 or second plurality of thermoelectric devices 171. For example, one, two, three, four, or more than one fastener 111 can be provided for each thermoelectric device of first plurality of thermoelectric devices 161 or second plurality of thermoelectric devices 171. As another example, one, two, three, four, or more than four thermoelectric devices of first plurality of thermoelectric devices 161 or second plurality of thermoelectric devices 171 can be provided for each fastener 111. The non-limiting embodiment of thermoelectric generating unit 100 illustrated in FIGS. 1A-1G includes four fasteners for every four thermoelectric devices 161 of the first plurality of thermoelectric devices and for every four thermoelectric devices 171 of the second plurality of thermoelectric devices. As noted above, thermoelectric devices 161, 171 optionally can be arranged in rows and columns. Fasteners 111 can be arranged in rows and columns that are laterally offset from the rows and columns of thermoelectric devices 161, 171 so as to pass between the rows and columns of thermoelectric devices 161, 171.

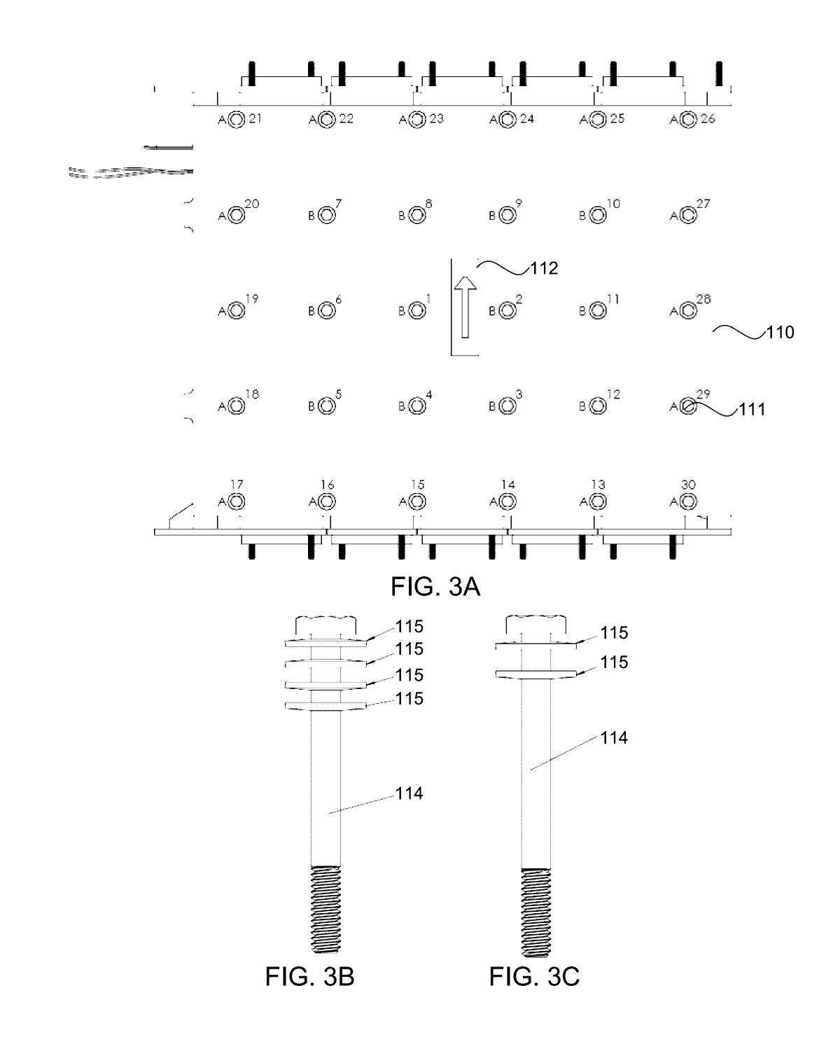

In some embodiments, fasteners 111 can include a bolt or screw. For example, in embodiments such as illustrated in FIGS. 3B and 3C, fasteners 111 can include bolt 114. Optionally, fasteners 111 also can include a nut that can engage the threading of the bolt or screw so as to comply compression between first cold-side plate 110 and second cold-side plate 130. In other embodiments, apertures through one or both of cold-side plate 110 and second cold-side plate 130 can include threading that can engage the threading of the bolt or screw so as to apply compression between first cold-side plate 110 and second cold-side plate 120. Optionally, fasteners 111 also can include a spring, a Belleville washer, or a spring washer disposed along the bolt or screw. Illustratively, such a spring, Belleville washer, or spring washer can permit thermal expansion of components of thermal generating unit 100 with changes in operating temperature, e.g., so as to reduce the likelihood of damage to unit 100 based on such thermal expansion, while maintaining compression between first cold-side plate 110 and second cold-side plate 120. Fasteners 111 can include different numbers of such springs, Belleville washers, or spring washers disposed along the bolts or screws than one another. For example, in the embodiment illustrated in FIG. 3B, the fastener includes bolt 114 and four Belleville washers 115, whereas in the embodiment illustrated in FIG. 3C, the fastener includes bolt 114 and two Belleville washers. One or more of the springs, Belleville washers, or spring washers can be arranged with opposite orientation to one or more other of the springs, Belleville washers, or spring washers so as to provide additional accommodation for thermal expansion.

In some embodiments, thermoelectric generating unit 100 optionally includes one or more layers configured to provide thermal insulation, electrical insulation, or both thermal and electrical insulation, between first plurality of thermoelectric devices 161 and one or both of hot-side heat exchanger 120 and first cold-side plate 110, or between second plurality of thermoelectric devices 171 and one or both of hot-side heat exchanger 120 and second cold-side plate 130. Such additional layers are represented in FIG. 1G as elements 150 and 180, which can be disposed at any suitable location within thermoelectric generating unit 100 and can include at least one of the following: a kapton film disposed between first side 126 of hot-side heat exchanger 120 and at least one thermoelectric device 161 of the first plurality of thermoelectric devices; a kapton film disposed between second side 127 of hot-side heat exchanger 120 and at least one thermoelectric device 171 of the second plurality of thermoelectric devices; a kapton film disposed between first cold-side plate 110 and at least one thermoelectric device 161 of the first plurality of thermoelectric devices; a kapton film disposed between second cold-side plate 130 and at least one thermoelectric device 171 of the second plurality of thermoelectric devices; a mica sheet disposed between first side 126 of hot-side heat exchanger 120 and at least one thermoelectric device 161 of the first plurality of thermoelectric devices; a mica sheet disposed between second side 127 of hot-side heat exchanger 120 and at least one thermoelectric device 171 of the second plurality of thermoelectric devices; a graphite sheet disposed between first side 126 of hot-side heat exchanger 120 and at least one thermoelectric device 161 of the first plurality of thermoelectric devices; a graphite sheet disposed between second side 127 of hot-side heat exchanger 120 and at least one thermoelectric device 171 of the second plurality of thermoelectric devices; a gap pad disposed between first cold-side plate 110 and at least one thermoelectric device 161 of the first plurality of thermoelectric devices; a gap pad disposed between second cold-side plate 130 and at least one thermoelectric device 171 of the second plurality of thermoelectric devices; an anodized layer disposed between first cold-side plate 110 and at least one thermoelectric device 161 of the first plurality of thermoelectric devices; and an anodized layer disposed between second cold-side plate 130 and at least one thermoelectric device 171 of the second plurality of thermoelectric devices. Exemplary embodiments of various suitable layer are described below with reference to FIGS. 2A-2C.

Optionally, thermoelectric generating unit 100 illustrated in FIGS. 1A-1G further can include spacers 125 disposed between first cold-side plate 110 and second cold-side plate 130. In some embodiments, spacers 125 can include a thermally insulative material that inhibits conduction of heat from hot-side heat exchanger 120 to one or both of first cold-side plate 110 and second cold-side plate 130 except via thermal pathways that pass through the thermoelectric devices 161, 171 respectively.

It should be understood that although FIGS. 1A-1G illustrate an embodiment that includes a hot-side heat exchanger and cold-side plates disposed on either side of respective pluralities of thermoelectric devices, other embodiments can include other numbers of hot-side heat exchangers, cold-side plates, and pluralities of thermoelectric devices. One exemplary embodiment can include a hot-side heat exchanger, a cold-side plate, a plurality of thermoelectric devices disposed between the hot-side heat exchanger and a cold-side plate, and a plurality of fasteners arranged so as to compress the plurality of thermoelectric devices. The hot-side heat exchanger, cold-side plate, thermoelectric devices, and fasteners can be arranged similarly as described elsewhere herein.

According to some embodiments, a thermoelectric generating unit (TGU) is a scalable and modular power producing device. In some embodiments, the TGU can be configured in different sizes and shapes so as suitably to fit a package space and/or to improve integration into a thermoelectric generator (TEG) system such as described in the above-mentioned U.S. Provisional Patent Application No. 62/059,092 and in U.S. patent application No. (TBA), filed on even date herewith and entitled “THERMOELECTRIC GENERATORS FOR RECOVERING WASTE HEAT FROM ENGINE EXHAUST, AND METHODS OF MAKING AND USING THE SAME,” but it should be understood that the present TGU suitably can be used independently of such a TEG, e.g., in a differently configured TEG, in another device, or as a standalone unit.

In some embodiments, the present TGU power output is greater than 300 W at inlet temperatures between 450° C. to 600° C. and flows between 25 g/s to 50 g/s. Illustratively, but not necessarily, the physical size of the TGU is 3 ft×3 ft×0.5 ft (10 ft³) or less with a mass of <75 kg. In some embodiments, operating voltage of the TGU can be greater than 300 V with an open circuit voltage which can be greater than 600 V.

In some embodiments, the TGU includes a cold side heat exchanger (CHX) or cold plate (also referred to herein as a cold-side plate) that can include a high performance heat exchanger, which can include one or more pin fins, straight fins, offset fins, or other enhanced heat exchanger constructions. In a nonlimiting example in which the CHX or cold-side plate includes a plurality of pin fins, in some embodiments the pin fins each can be about 0.5 mm in diameter with 0.5 mm spacing relative to one another in an inline configuration (staggered configurations or other arrangements, and other dimensions and spacings, are also possible). In some embodiments, microchannel heat transfer effectively cools the cold side of the TGU. As used herein, the terms “about” and “approximately” are intended to mean plus or minus ten percent of the stated value.

In some embodiments, the CHX or cold-side plate is constructed such that both the inlet and outlet of the coolant flow are on the same side of the plate as one another. In some embodiments, this configuration provides U flow. Illustratively, such a U flow configuration can provide higher flow through the CHX or cold-side plate, which can increase both heat transfer and pressure drop. An illustrative configuration in which both the inlet and outlet of the coolant flow are on the same side of the plate as one another can facilitate easier access to the coolant fluid ports (inlet and outlet) for assembly and maintenance purposes. In some embodiments, in addition to the coolant fluid ports, the electrical connections are also both on the same side of the TGU as one other and as the cooling fluid ports. Illustratively, such a configuration can facilitate all of the connections, both fluid and electrical, to be made on the same side of the TGU (or TEG, in certain embodiments), which can simplify assembly and maintenance procedures.

In some embodiments, dielectric insulation of the TGU can be provided in multiple ways. In one nonlimiting example, dielectric insulation can provided at the powercard or TE (thermoelectric) device level with ceramic substrates partially, substantially, or completely isolating the electrical components from the CHX (cold-side plate) or the hot-side heat exchanger (HHX), or both. Additionally, or alternatively, in some embodiments, e.g., embodiments in which the ceramic substrates are split for thermal expansion mismatch accommodation and/or the TE devices are unsealed, or both, other dielectric protection can be used. For example, the CHX or cold-side plate can be anodized, which can provide a relatively thin, electrically isolating layer. Additionally, or alternatively, another exemplary configuration adds a thin layer of kapton or mica to the thermal interface materials (TIMs) to provide electrical isolation. Illustratively, such a thin layer can be applied to either the hot or cold side TIMs or both sides. Additionally, or alternatively, in some embodiments, voltage leakage from the connections between the TE devices can be inhibited by taping the connections between TE devices with electrical tape or kapton so as to partially, substantially, or completely electrically isolate such connections. Additionally, or alternatively, in some embodiments, a conformal coating can be added so as to partially, substantially, or completely electrically isolate the connections between TE devices.

FIGS. 2A-2C schematically illustrate views of an exemplary thermoelectric assembly for use in a thermoelectric generating unit such as illustrated in FIGS. 1A-1G, according to some embodiments. Thermoelectric assembly 160 illustrated in FIGS. 2A-2C can correspond to one or both of thermoelectric assembly 160 and thermoelectric assembly 170 described above with reference to FIGS. 1A-1G.

Thermoelectric assembly 160 illustrated in FIGS. 2A-2C can include first insulation layer 210, circuit board 220 including a plurality of thermoelectric devices 221 disposed thereon, thermal insulation layer 230, second insulation layer 240, third insulation layer 250, fourth insulation layer 260, fifth insulation layer 270, sixth insulation layer 280, and adhesive 290.

First insulation layer 210 can be disposed over circuit board 220 and can be configured so as to provide thermal insulation, electrical insulation, or both thermal and electrical insulation between thermoelectric devices 221 disposed on circuit board 220 and a substantially flat cold-side plate, e.g., first cold-side plate 110 or second cold-side plate 130 described above with reference to FIGS. 1A-1G. In one non-limiting embodiment, first insulation layer 210 includes one or more films of kapton, two or more films of kapton, or three or more films of kapton, e.g., four films of kapton having a thickness of about 0.001 inches each.

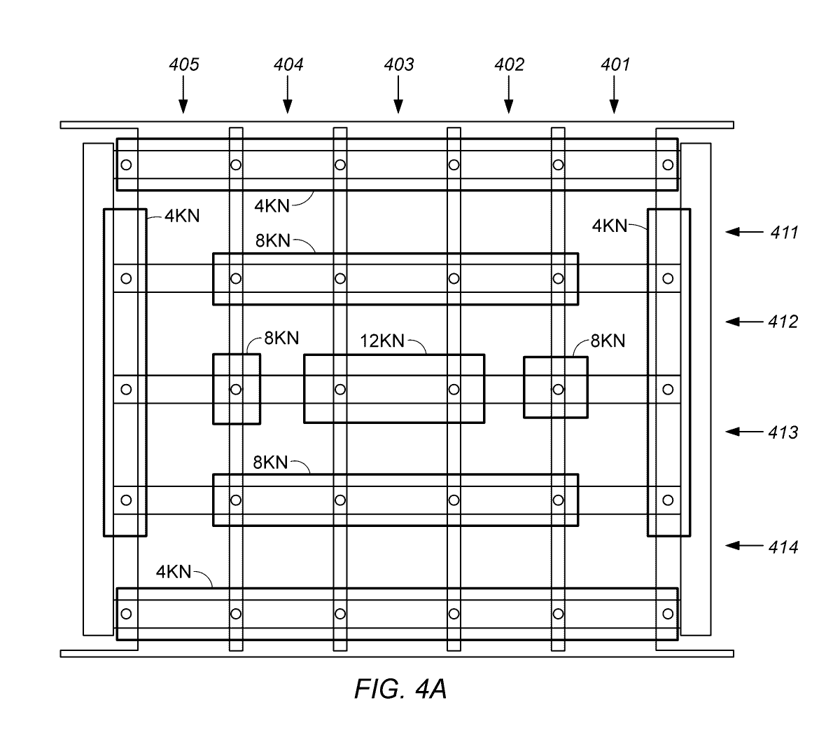

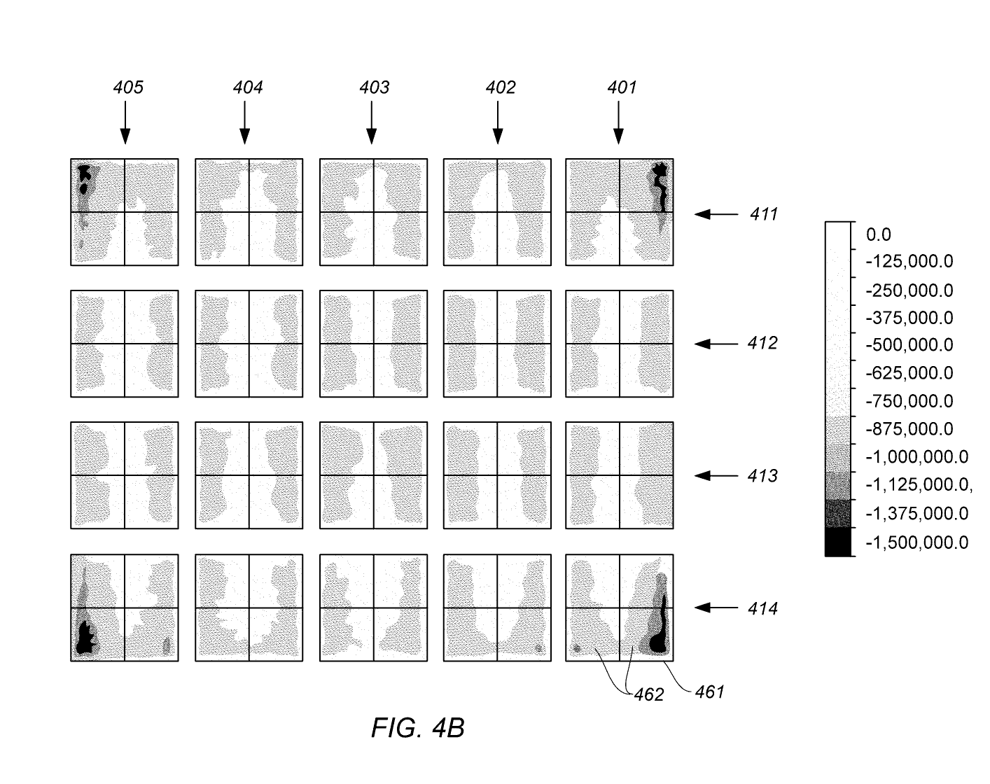

Circuit board 220 is disposed over thermal insulation layer 230 and includes a plurality of thermoelectric devices 221 disposed thereon. The thermoelectric devices 221 optionally can be grouped together in assemblies that include any suitable number of thermoelectric devices 221, e.g., one, more than one, more than two, or more than three thermoelectric devices 221, e.g., four thermoelectric devices. Thermoelectric devices 221, or the assemblies of thermoelectric devices 221, can be arranged in columns and rows in a manner such as illustrated in FIGS. 4A-4B.

Thermal insulation layer 230 can be disposed over second insulation layer 240 and can include any suitable thermal insulation material that can inhibit heat from being dissipated from the hot side to the cold side without going through thermoelectric devices 221, and also can inhibit thermal shorting in regions where thermoelectric devices 221 are not present.

Second insulation layer 240, third insulation layer 250, fourth insulation layer 260, fifth insulation layer 270, and sixth insulation layer 280 can be selected so as to provide any suitable degree of thermal insulation, electrical insulation, or both thermal and electrical insulation between circuit board 220 and thermoelectric devices 221 disposed therein, and a hot-side heat exchanger, e.g., hot-side heat exchanger 120 described above with reference to FIGS. 1A-1G. In one non-limiting embodiment, second insulation layer 240 is disposed over third insulation layer 250 and includes one or more films of kapton, two or more films of kapton, or three or more films of kapton, e.g., one film of kapton having a thickness of about 0.001 inch. In some embodiments, third insulation layer 250 is disposed over fourth insulation layer 260 and fifth insulation layer 270 and can include one or more graphite sheets, two or more graphite sheets, or three or more graphite sheets, e.g., one graphite sheet having a thickness of about 0.25 inches. The dotted lines at 251 are intended to indicate the exemplary relative alignment between third insulation layer 250, fourth insulation layer 260, and fifth insulation layer 270. In some embodiments, fourth insulation layer 260 is disposed adjacent to fifth insulation layer 270 and under only a subset of thermoelectric devices 121 (with one or more layers disposed in between), and can include one or more graphite sheets, two or more graphite sheets, or three or more graphite sheets, e.g., one graphite sheet having a thickness of about 0.25 inches. In some embodiments, fifth insulation layer 270 is disposed adjacent to sixth insulation layer 280, adjacent to fourth insulation layer 260, and under only a subset of thermoelectric devices 121 (with one or more layers disposed in between), and can include one or more mica sheets, two or more mica sheets, or three or more mica sheets, e.g., ten mica sheets having a thickness of about 0.008 inches each. In some embodiments, sixth insulation layer 280 is disposed adjacent to fifth insulation layer 270, and under only a subset of thermoelectric devices 121 (with one or more layers disposed in between), and can include one or more mica sheets, two or more mica sheets, or three or more mica sheets, e.g., seven mica sheets having a thickness of about 0.020 inches each. The mica sheets of fifth insulation layer 270 and sixth insulation layer 280 optionally can include a combination of mica and graphite. Adhesive 290, e.g., kapton tape, can be used to adhere the different insulation layers to one another and to second insulation layer 240 in a manner such as illustrated in FIGS. 2B-2C.

Note that in the embodiment illustrated in FIG. 2A, sixth insulation layer 280 can be disposed adjacent to the inlets of the one or more discrete channels of the hot-side heat exchanger, e.g., where the fluid carrying the waste heat can be the hottest. Fifth insulation layer 270 can be disposed adjacent to a central portion of the one or more discrete channels of the hot-side heat exchanger, e.g., where the fluid carrying the waste heat is cooler than at the inlet. Fourth insulation layer 260 can be disposed adjacent to the outlets of the one or more discrete channels of the hot-side heat exchanger, e.g., where the fluid carrying the waste heat can be still cooler than in the central portion. Sixth insulation layer 280 can provide greater thermal insulation between thermoelectric devices 221 and the hot-side heat exchanger than does fifth insulation layer 270, an fifth insulation layer 270 can provide greater thermal insulation between thermoelectric devices 221 and the hot-side heat exchanger than does fourth insulation 260. As such, a suitable amount of heat can be transmitted through the respective insulation layer 260, 270, or 280 to the thermoelectric devices 221 disposed over that layer, while sufficiently protecting the thermoelectric devices 221 from being damaged by that heat.

Note that the particular arrangement of elements in FIGS. 2A-2C is intended to be purely illustrative, and not limiting. One or more of the insulation layers suitably can be omitted or modified so as to facilitate transfer of heat from the fluid to the thermoelectric devices, while suitably protecting the thermoelectric devices from damage by that heat.

In one exemplary, nonlimiting configuration, the TE devices are connected together on a circuit board or printed wiring harness, so as to reduce the complexity and amount of wiring. In such embodiments, the traces of the circuit board can be properly electrically isolated from one another. In some embodiments, the TGU can include a configuration of clamping bolts that go through the circuit board or wiring harness. In some embodiments, so as to inhibit electrical continuity, contact, or communication between the bolts and the circuit board or wiring harness, the bolts can be electrically isolated, e.g., by applying kapton tape to them and/or a high temperature electrically isolating coating.

An exemplary TGU prepared as provided herein was tested on a hi pot tester, passing at voltages greater than 2 kV. The exemplary TGU was also tested with a mega-ohm meter where fully parallel (all heat exchangers connected together) resistances were measured exceeding 50 Mohm.

In one nonlimiting, illustrative embodiment, the TGU includes two CHX or cold-side plates and one set of hot heat exchanger (HHX) channels sandwiching two sets of TE devices or powercards connected electrically together on a circuit board or printed wiring harness. Illustratively, the fluid flows of the CHX (cold-side plate) and HHX can be configured in a cross flow construction relative to one another, although counter and parallel flow configurations are also options. An alternative construction allows for alternating CHX (cold-side plate) and HHX with the TE circuit board sandwiched in between, and in some embodiments there can be one more CHX (cold-side plate) than HHX set.

In some embodiments, the HHX set includes a plurality of separate HHX channels, e.g., two, three, four, five, six, seven, eight, nine, ten, or more than ten HHX channels, connected fluidically in parallel with one another so as to enhance thermal expansion protection. In some embodiments, such a configuration can reduce thermal stress in the TGU. In some embodiments, hot heat exchangers can experience exemplary temperatures from −40° C. or less to 600° C., or greater. In some embodiments, by separating the hot heat exchangers (channels of the MIX) from one another, the length of the hot heat exchangers can be reduced and therefore the absolute expansion can be reduced. In some embodiments, expansion occurs in between hot heat exchanger channels, which can reduce effects on interface with the rest of the TGU. In some embodiments, such a configuration can increase repeatability of part, thus, in some embodiments, reducing cost through volume. In some embodiments, such a configuration also can improve quality of hot heat exchanger build, e.g., by reducing maximum length of the fin pack, braze surface, and the like. Additionally, the modular configuration of some embodiments can allow for integration into TGUs of various sizes by adding or removing channels.

So as to maintain satisfactory thermal contact between the HHX, cold-side plate(s), and thermoelectric devices, one or more fasteners can be configured so as to apply different forces than one or more other fasteners across the TGU. For example, in certain embodiments of a TGU, e.g., as described above with reference to FIGS. 1A-1G, a first subset of the first plurality of thermoelectric devices 161 is centrally disposed and a second subset of the first plurality of thermoelectric devices 171 is peripherally disposed. Illustratively, a first subset of the plurality of fasteners 111 apply a first force to the first subset of the first plurality of thermoelectric devices and a second subset of the plurality of fasteners 111 apply a second force to the second subset of the first plurality of thermoelectric devices, where the first force is greater than the second force. In one nonlimiting example, the first force is at least 1.5 times the second force. Optionally, in some embodiments, a third subset of the first plurality of thermoelectric devices 161 can be disposed between the first subset of the first plurality of thermoelectric devices 161 and the third subset of the first plurality of thermoelectric devices 161. A third subset of the plurality of fasteners 111 apply a third force to the third subset of the first plurality of thermoelectric devices 161, where the third force is less than the first force and greater than the second force. In one nonlimiting example, the first force is about 1.5 times the third force, and the first force is about 3 times the second force. Illustratively, the first force can be about 11-13 kN, the third force can be about 7-9 kN, and the second force can be about 3-5 kN. In some embodiments, such a distribution of forces can provide a substantially uniform pressure of the TGU, e.g., a substantially uniform pressure of 80 psi across the TGU.

For example, in some embodiments, the bolt pattern for the TGU layout utilizes unequal bolt torqueing. In some embodiments, controlling interface pressure at hot and cold junctions of the TGU can be useful so as to enhance performance. In some embodiments, by reducing distance between bolts, pressure can be controlled locally. In some embodiments, bolt loading is selected so as to account for, or to offset, stiffness effects of other TGU components. For example, as noted further above, fasteners 111 can include a bolt or screw, and also can include a spring, a Belleville washer, or a spring washer disposed along the bolt or screw. Illustratively, such a spring, Belleville washer, or spring washer can permit thermal expansion of components of thermal generating unit 100 with changes in operating temperature, e.g., so as to reduce the likelihood of damage to unit 100 based on such thermal expansion, while maintaining compression between first cold-side plate 110 and second cold-side plate 120. Referring again to the above-mentioned subsets, the first subset of the plurality of fasteners optionally can include a greater number of springs, Belleville washers, or spring washers disposed along the bolts or screws of that subset than does the second subset of the plurality of fasteners.

For example, FIGS. 3A-3C schematically illustrate exemplary arrangements of fasteners for use in a thermoelectric generating unit such as illustrated in FIGS. 1A-1G, according to some embodiments. FIG. 3A illustrates a top view of first cold-side plate 110 similar to that described above with reference to FIGS. 1A-1G, with annotations representing an exemplary fastener configuration at different locations through first cold-side plate 110. More specifically, in FIG. 3A, the annotation “A” indicates that the fastener configuration illustrated in FIG. 3B is used, and the annotation “B” indicates that the fastener configuration illustrated in FIG. 3C is used. The annotations 1-30 indicate the number designation of the respective fasteners. Table 1 below summarizes one exemplary set of torques that can be applied to the various fasteners (e.g., bolts) represented in FIG. 3A on different passes:

TABLE 1
SPECIFICATION: BOLT TORQUE (IN-LBS)

| BOLT # | PASS #1 | PASS #2 | PASS #3 | PASS #4 | PASS #5 |
|---|---|---|---|---|---|
| 1-2 | 30 | 60 | 90 | 120 | 120 |
| 3-12 | 20 | 40 | 60 | 80 | 80 |
| 13-30 | 10 | 20 | 30 | 40 | 40 |

FIG. 4A schematically illustrates one nonlimiting example of an arrangement of fasteners for use in a thermoelectric generating unit such as illustrated in FIGS. 1A-1G, according to some embodiments. For example, FIG. 4A illustrates a schematic showing one exemplary embodiment in which unequal fastener (bolt) torque values can be used to create a partially, substantially, or completely uniform pressure on or across some or all of the TE devices of the TGU. In FIG. 4A, a force of about 12 kN is applied to a first subset of thermoelectric devices that is centrally disposed, a force of about 4 kN is applied to a second subset of thermoelectric devices that is peripherally disposed, and a force of about 8 kN is applied to a third subset of thermoelectric devices that is disposed between the first subset and the second subset. FIG. 4B schematically illustrates one nonlimiting example of a distribution of pressures that can be obtained using the arrangement of fasteners illustrated in FIG. 4A. For example, FIG. 4B illustrates exemplary simulation results showing substantial pressure uniformity on each of the TE devices in the circuit board in the TGU based on the nonlimiting, exemplary bolt torque values illustrated in FIG. 4A. In FIG. 4B, it can be seen that each assembly 461 includes four TE devices 462. Additionally, in FIGS. 4A and 4B, it can be seen that the assemblies are arranged in columns 401-405 and rows 411-414 and that the fasteners are disposed between the columns and rows.

Additionally, or alternatively, in some embodiments, the thermal interface along the length of the HHX in the flow direction can be varied. Such a configuration can facilitate the use of the TGU in higher temperature exhaust applications by reducing the TE junction temperature at the hottest location below its upper limit. Such a configuration also can improve consistency of the hot junction temperature of the TE devices, e.g., can partially, substantially, or completely equalize the hot junction temperature of the TE devices, such that the TE devices can operate at a suitable load, illustratively, at an optimal load.

Additionally, or alternatively, in some embodiments, compact thermal expansion management is utilized. For example, in some embodiments, the TGU can undergo thermal expansion during operation (such expansion can be steady state or cyclic, or both steady state and cyclic). In some embodiments, the incorporation of Belleville washers can facilitate bolt (fastener) loads—and therefore pressure on the TE devices—to remain relatively stable over a portion of or over the entire operating range of the TGU. In some embodiments, a gap pad can be used as an interface between CHX and a cold junction of thermal interface material, and in some embodiments, such gap pad can be made thicker than thermally necessary so as to partially, substantially, or completely absorb some of such expansion.

Additionally, or alternatively, in some embodiments, strategic heat transfer fin location can be utilized within either the HHX and/or the CHX so as to enhance localized heat transfer and to reduce heat exchanger pressure drop. For example, TE devices need not necessarily be located across the entire area of an HHX and/or CHX. In some embodiments, fins are located where needed, and need not necessarily be located where fins are not needed. In addition, in some embodiments, fin density can be varied in different areas of the TGU so as to enhance thermal impedance match in different areas of the TGU.

Additionally, or alternatively, in some embodiments, tortuous path sealing can be utilized so as to inhibit exhaust gas leakage within the TGU. In one nonlimiting example, scallop and gusset features can be utilized so as to inhibit exhaust gas leakage.

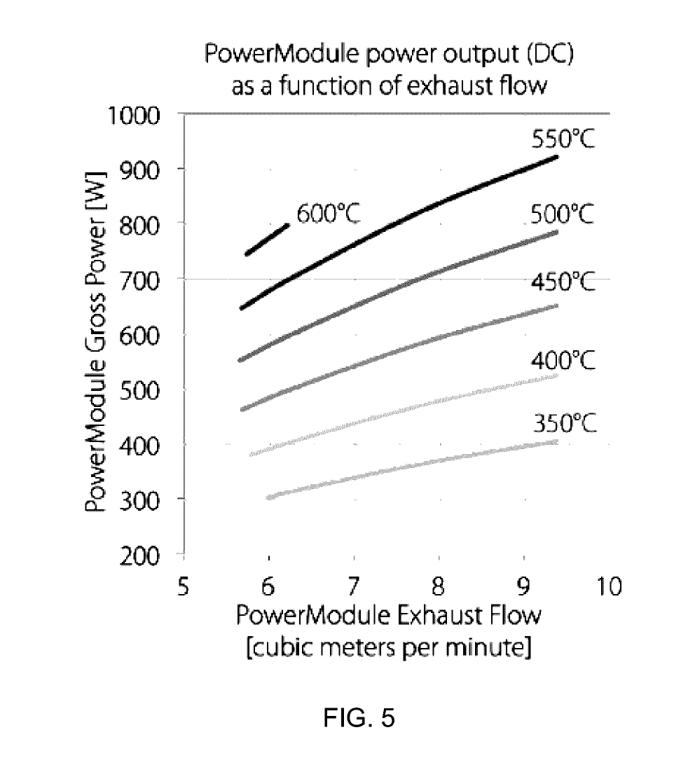

FIG. 5 illustrates a plot of exemplary power output as a function of exhaust flow for a thermoelectric generating unit such as illustrated in FIGS. 1A-1G, according to some embodiments. In FIG. 5, it can be understood that based upon an increase in the exhaust flow through the hot-side heat exchanger of the present thermoelectric generating unit (“PowerModule”), the gross power produced by the thermoelectric generating unit increases. Additionally, in FIG. 5, it can be understood that based upon an increase in the inlet temperature of the exhaust flow through the hot-side heat exchanger of the present thermoelectric generating unit (“PowerModule”), the gross power produced by the thermoelectric generating unit increases.

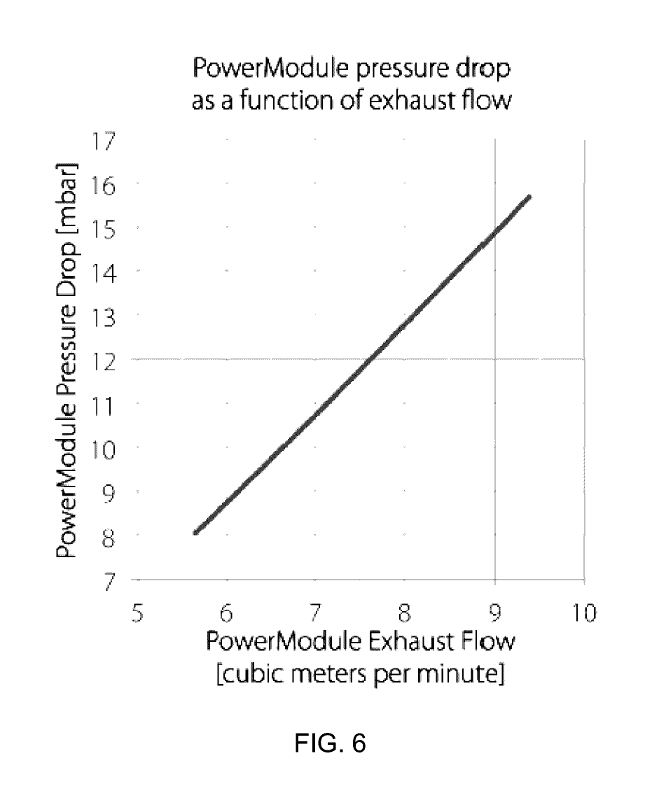

FIG. 6 illustrates a plot of exemplary pressure drop as a function of exhaust flow for a thermoelectric generating unit such as illustrated in FIGS. 1A-1G, according to some embodiments. In FIG. 6, it can be understood that based upon an increase in the exhaust flow through the hot-side heat exchanger of the present thermoelectric generating unit (“PowerModule”), the pressure drop within the thermoelectric generating unit increases.

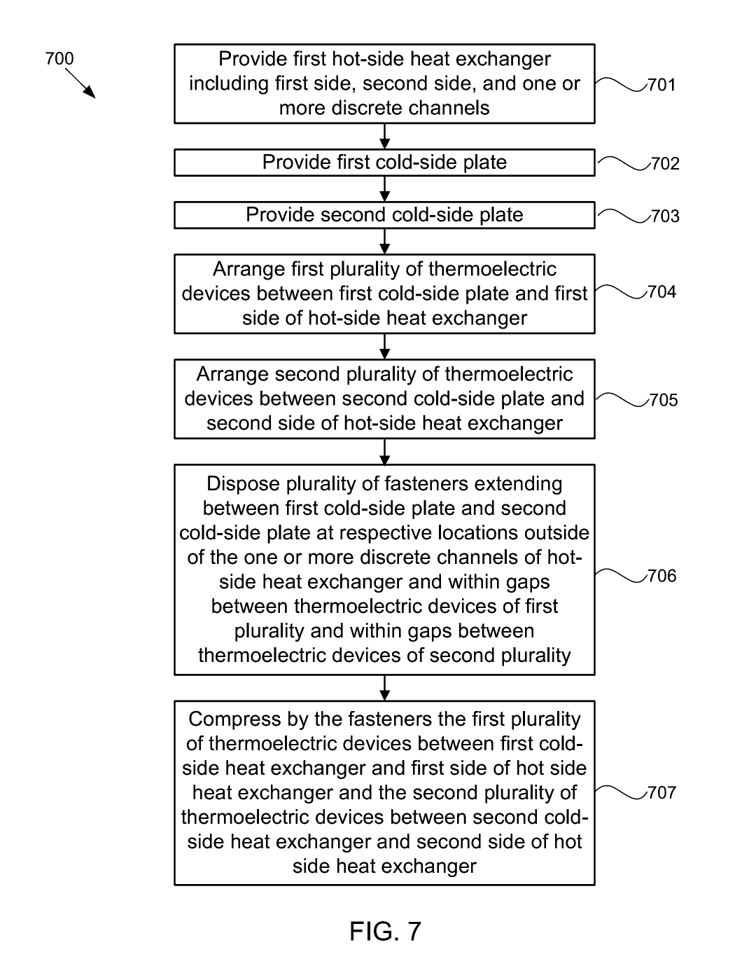

FIG. 7 schematically illustrates steps in an exemplary method of preparing a thermoelectric generating unit, according to some embodiments. Method 700 includes providing a hot-side heat exchanger including a first side, a second side, and one or more discrete channels (701). Exemplary embodiments of hot-side heat exchangers are provided elsewhere herein, e.g., with reference to FIGS. 1A-1G.

Method 700 illustrated in FIG. 7 also includes providing a substantially flat first cold-side plate (702) and providing a substantially flat second cold-side plate (703). Exemplary embodiments of cold-side plates are provided elsewhere herein, e.g., with reference to FIGS. 1A-1G.

Method 700 illustrated in FIG. 7 also includes arranging a first plurality of thermoelectric devices between the first cold-side plate and the first side of the hot-side heat exchanger (704) and arranging a second plurality of thermoelectric arranged between the second cold-side plate and the second side of hot-side heat exchanger (705). Exemplary arrangements of thermoelectric devices between a cold-side plate and a heat exchanger are provided elsewhere herein, e.g., with reference to FIGS. 1A-1G, 2A-2C, 3A, and 4A-4B.

Method 700 illustrated in FIG. 7 also includes disposing a plurality of fasteners extending between the first cold-side plate and the second cold-side plate at respective locations outside of the one or more discrete channels of the hot-side heat exchanger and within gaps between the thermoelectric devices of the first plurality and within gaps between the thermoelectric devices of the second plurality (706). Exemplary arrangements and configurations of fasteners are provided elsewhere herein, e.g., with reference to FIGS. 1A-1G, 3A-3C, and 4A-4B.

Method 700 illustrated in FIG. 7 further includes compressing by the fasteners the first plurality of thermoelectric devices between the first cold-side plate and the first side of the hot-side heat exchanger and the second plurality of thermoelectric devices between the second cold-side plate and the second side of the hot-side heat exchanger (707). Exemplary torques with which the fasteners can be tightened and exemplary forces and pressures that can be exerted by such fasteners are provided elsewhere herein, e.g., with reference to FIGS. 1A-1G, 3A-3C, and 4A-4B.

Optionally, method 700 includes centrally disposing a first subset of the first plurality of thermoelectric devices; peripherally disposing a second subset of the first plurality of thermoelectric devices; applying a first force to the first subset of the first plurality of thermoelectric devices with a first subset of the plurality of fasteners; and applying a second force to the second subset of the first plurality of thermoelectric devices with a second subset of the plurality of fasteners, wherein the first force is greater than the second force, e.g., in a manner such as described above with reference to FIGS. 3A-3C and 4A-4B. In one non-limiting example, the first force is at least 1.5 times the second force. In some embodiments of method 700 illustrated in FIG. 7, each fastener can include a bolt or screw; and a spring, a Belleville washer, or a spring washer disposed along the bolt or screw. Optionally, the first subset of the plurality of fasteners includes a greater number of springs, Belleville washers, or spring washers disposed along the bolts or screws of that subset than does the second subset of the plurality of fasteners.

Method 700 optionally also can include disposing a third subset of the first plurality of thermoelectric devices is between the first subset of the first plurality of thermoelectric devices and the third subset of the first plurality of thermoelectric devices; and applying a third force to the third subset of the first plurality of thermoelectric devices with a third subset of the plurality of fasteners, wherein the third force is less than the first force and greater than the second force, e.g., in a manner such as described above with reference to FIGS. 3A-3C and 4A-4B. In one non-limiting example, the first force can be about 1.5 times the third force, and the first force can be about 3 times the second force. For example, the first force can be about 11-13 kN, the third force can be about 7-9 kN, and the second force can be about 3-5 kN. In some embodiments, such a distribution of forces can provide a substantially uniform pressure of the TGU, e.g., a substantially uniform pressure of 80 psi across the TGU.

Some embodiments of method 700 further include arranging the first plurality of thermoelectric devices in columns and rows between the first cold-side plate and the first side of the hot-side heat exchanger; and respectively disposing the fasteners within gaps between the columns and rows. In one nonlimiting example, method 700 can include disposing four fasteners for every four thermoelectric devices of the first plurality of thermoelectric devices and for every four thermoelectric devices of the second plurality of thermoelectric devices. But it should be understood that other numbers of fasteners suitably can be used.

In some embodiments of method 700, the hot-side heat exchanger further includes fins disposed within each of the one or more discrete channels. Optionally, the fins can include stainless steel, nickel plated copper, or stainless steel clad copper. Optionally, a density of the fins within each of the one or more discrete channels is at least 12 fins per inch.

In some embodiments of method 700, the hot-side heat exchanger includes at least one threaded rod, and method 700 further can include sealingly coupling the hot-side heat exchanger to a pipe flange via the at least one threaded rod.

In some embodiments of method 700, the first cold-side plate further includes pin fins, straight fins, or offset fins. Optionally, the pin fins can be arranged in an in-line arrangement or in a staggered arrangement, or include brazed offset pin fins.

Some embodiments of method 700 further include disposing the first plurality of thermoelectric devices on a circuit board.

In some embodiments of method 700, the first plurality of thermoelectric devices include a thermoelectric material, the thermoelectric material being selected from the group consisting of: tetrahedrite, magnesium silicide, magnesium silicide stannide, silicon, silicon nanowire, bismuth telluride, skutterudite, lead telluride, TAGS (tellurium-antimony-germanium-silver), zinc antimonide, silicon germanium, and a half-Heusler compound.

In some embodiments of method 700, at least one of the first cold-side plate and the second cold-side plate includes a high efficiency cold-side heat exchanger; and the hot-side heat exchanger includes a high efficiency hot-side heat exchanger.

In some embodiments of method 700, the first cold-side plate includes an inlet for coolant inflow and an outlet for coolant outflow, wherein the inlet and outlet are on the same side of the first cold-side plate as one another.

Some embodiments of method 700 further include at least one of the following: disposing a kapton film between the first side of the hot-side heat exchanger and at least one thermoelectric device of the first plurality of thermoelectric devices; disposing a kapton film between the first cold-side plate and at least one thermoelectric device of the first plurality of thermoelectric devices; disposing a mica sheet between the first side of the hot-side heat exchanger and at least one thermoelectric device of the first plurality of thermoelectric devices; disposing a graphite sheet between the first side of the hot-side heat exchanger and at least one thermoelectric device of the first plurality of thermoelectric devices; disposing a gap pad between the cold-side plate and at least one thermoelectric device of the first plurality of thermoelectric devices; and disposing an anodized layer between the cold-side plate and at least one thermoelectric device of the first plurality of thermoelectric devices.

The following provides a description of one exemplary, nonlimiting embodiment of the present TGU:
Alphabet Energy introduced the world's largest thermoelectric generator today, which captures exhaust heat and turns it into a new source of electricity.
The company's first product, called the E1, attaches to an exhaust stack, and captures waste heat and uses Alphabet's patented thermoelectric materials to convert it to electricity. Thermoelectrics use a heat differential to create electricity; one side is hot, and the other is cold, and the temperature differential between the two forces electrons to create a current.
The product introduction is the first for the mid-stage startup, which was founded in 2009 at Lawrence Berkeley National Laboratory.
While NASA has used thermoelectrics since the 1950s, materials costs made them cost-prohibitive. However, new advancements in silicon and tetrahedrite have led Alphabet to create highly efficient thermoelectric materials using abundant resources. Thermoelectrics are unique because they are solid-state; which means the E1 has no moving parts, no working fluids and requires no maintenance.
“With the E1, waste heat is now valuable,” said Alphabet Energy CEO and Founder Matthew L. Scullin. “Saving fuel has the potential to be one of the biggest levers a company has in reducing operating expenses. With the E1, that potential is finally realized with the world's first waste-heat recovery product that meets the mining's and oil & gas industry's criteria for a simple, strong, and reliable solution.”
The E1 generates up to 25 kW per 1,000 kWe diesel generator, which means 1% energy efficiency. The electricity the E1 creates can power additional hardware and/or augment power to existing systems, reducing electrical load and in turn, reducing fuel consumption and operating costs.
These turnkey systems ship in a single, standard shipping container and save more than 60,000 liters of diesel fuel per year when operating on a 1,000 kW diesel engine.
The E1 requires no engine modifications and is installed during a simple process that involves exhaust coupling and electrical hookup. Standard connection is complete in less than two hours. All updates to the host engine's (or turbine's) exhaust system are performed within a standard engine maintenance service interval and the E1 complies with all major engine manufacturer back pressure limits and warranty specs.
In addition to improving fuel economy and producing high quality electricity, the E1:
   Attenuates engine exhaust noise by up to 23 dBA,
   Reduces engine exhaust heat signatures by up to 30%,
   Reduces diesel emissions: C02—198,000 lbs/yr; NOx—3,306 lbs/yr; CO—343 lbs/yr; HC—103 lbs/yr; PM—52 lbs/yr.
Alphabet Energy's thermoelectric materials are a platform technology with a wide array of potential applications including power generation associated: remote sensors, surveillance, telemetry, automobiles, trucks, locomotives, mining equipment, ships, jet engines, factory exhaust flues, and many more.
Based on groundbreaking materials science R&D at the Lawrence Berkeley National Laboratory in the US, Alphabet Energy has over 50 patents registered or pending. The top caliber team includes many of the top minds in thermoelectrics and materials science and a wealth of experience from the oil & gas, automotive, and power generation industries. Alphabet Energy has raised over $30 million in funding from top investors including TPG and Encana.

The following provides a description of another exemplary, nonlimiting embodiment of the present TGU:

Saving fuel has the potential to be one of the biggest levers a company has in reducing operating expenses. With the E1, that potential is finally realized with the world's first waste-heat recovery product that meets the mining's and oil & gas industry's criteria for a simple, strong, and reliable solution.

When we set out to build the world's first industrial-scale thermoelectric generator, we knew it had to behave as a piece of simple industrial equipment rather than a complex power plant. We put together a team that combined decades of experience in the oil & gas, mining, engine, and burner industries with the brightest minds in solid-state power generation.

We talked to hundreds of customers who spend their days looking for ways to improve operational efficiency and profitability in their businesses, and who have the most demanding technical requirements for equipment in the field.

What resulted was the E1. The E1 takes waste heat from exhaust and simply turns it into electricity. The result is an engine that needs less fuel to deliver the same power.

The E1's benefits are delivered instantly: several percent savings in fuel and a very short payback time on a small amount of up-front capital. The E1 is optimized for continuous engines 800 to 1400 kW in size running diesel or natural gas, but works on any engine or exhaust source.

But what sets the E1 apart is its strength, reliability, and simplicity, requiring virtually no maintenance or operation.

Installation can occur in just 2 hours with almost no up-front scope. Every part needed comes inside the E1's simple and easily transportable 16- or 20-foot shipping container. There are only two points of connection: the E1 flanges directly onto the exhaust pipe, then wiring is then run from the E1 to the site's main breaker.

The E1's operation is simple and reliable. Exhaust from the engine is channeled through 32 modules that generate power, in the solid-state with no moving parts, using Alphabet's proprietary PowerBlocks thermoelectric technology.

The DC electricity is delivered to the pre-packaged power electronics which inverts the power to AC at the same phase and voltage that the engine delivers. The cooled exhaust then flows up and out of the container at about 200 degrees Celsius. All the while, the E1's pre-packaged radiators keep the modules cool.

The modules inside the E1 are revolutionary because they include the only efficient, low-cost thermoelectrics ever made. Like everything in the E1, they've been rigorously tested in the field to ensure at least a 10 year life. They are fully upgradeable, making the E1 the only upgradeable power generator in existence. As Alphabet continues it advances in thermoelectric materials new modules can be swapped in for old ones, in the same system, to generate even more fuel savings.

With the E1, waste heat is now valuable. Some of the smartest, most forward-thinking companies in the world are using Alphabet's thermoelectric generator, and we're excited to be able to help a range of industries reduce their fuel cost and drive operating margins to build more efficient, profitable businesses.

### Other Alternative Embodiments

In another example, a thermoelectric generating unit includes a hot-side heat exchanger including a first side, a second side, and one or more discrete channels; a first cold-side plate; and a second cold-side plate. The thermoelectric generating unit further can include a first plurality of thermoelectric devices arranged between the first cold-side plate and the first side of the hot-side heat exchanger; and a second plurality of thermoelectric devices arranged between the first cold-side plate and the first side of the hot-side heat exchanger. The thermoelectric generating unit further can include a plurality of fasteners disposed within gaps between the thermoelectric devices of the first plurality, the fasteners compressing the first plurality of thermoelectric devices between the first cold-side plate and the first side of the hot-side heat exchanger. The plurality of fasteners further can be disposed within gaps between the thermoelectric devices of the second plurality, the fasteners compressing the second plurality of thermoelectric devices between the second cold-side plate and the second side of the hot-side heat exchanger. The fasteners can extend from the first cold-side plate to the second cold-side plate at respective locations outside of the one or more discrete channels of the hot-side heat exchanger. Non-limiting examples of such an embodiment are provided herein, e.g., with reference to FIGS. 1A-1G, 3A-3C, 4A, and 4B.

In another example, a method of assembling a thermoelectric generating unit includes providing a hot-side heat exchanger including a first side, a second side, and one or more discrete channels. The method also can include providing a substantially flat first cold-side plate; and providing a substantially flat second cold-side plate. The method also can include arranging a first plurality of thermoelectric devices between the first cold-side plate and the first side of the hot-side heat exchanger; and arranging a second plurality of thermoelectric arranged between the second cold-side plate and the second side of hot-side heat exchanger. The method also can include disposing a plurality of fasteners extending between the first cold-side plate and the second cold-side plate at respective locations outside of the one or more discrete channels of the hot-side heat exchanger and within gaps between the thermoelectric devices of the first plurality and within gaps between the thermoelectric devices of the second plurality. The method also can include compressing by the fasteners the first plurality of thermoelectric devices between the first cold-side plate and the first side of the hot-side heat exchanger and the second plurality of thermoelectric devices between the second cold-side plate and the second side of the hot-side heat exchanger. Non-limiting examples of such an embodiment are provided herein, e.g., with reference to FIGS. 1A-1G, 3A-3C, 4A, 4B, and 7.

Although specific embodiments of the present invention have been described, it will be understood by those of skill in the art that there are other embodiments that are equivalent to the described embodiments. For example, various embodiments and/or examples of the present invention can be combined. Accordingly, it is to be understood that the invention is not to be limited by the specific illustrated embodiments, but only by the scope of the appended claims.

What is claimed:

1. A thermoelectric generating unit, comprising:
a hot-side heat exchanger including a first side, a second side, and one or more discrete channels;
a substantially flat first cold-side plate;
a substantially flat second cold-side plate;
a first plurality of thermoelectric devices arranged between the first cold-side plate and the first side of the hot-side heat exchanger;
a second plurality of thermoelectric devices arranged between the second cold-side plate and the second side of the hot-side heat exchanger; and
a plurality of fasteners extending between the first cold-side plate and the second cold-side plate at respective locations outside of the one or more discrete channels of the hot-side heat exchanger,
the fasteners being disposed within gaps between the thermoelectric devices of the first plurality and within gaps between the thermoelectric devices of the second plurality,
the fasteners compressing the first plurality of thermoelectric devices between the first cold-side plate and the first side of the hot-side heat exchanger and compressing the second plurality of thermoelectric devices between the second cold-side plate and the second side of the hot-side heat exchanger.

2. The thermoelectric generating unit of claim 1, wherein:
a first subset of the first plurality of thermoelectric devices is centrally disposed and a second subset of the first plurality of thermoelectric devices is peripherally disposed;
a first subset of the plurality of fasteners apply a first force to the first subset of the first plurality of thermoelectric devices;
a second subset of the plurality of fasteners apply a second force to the second subset of the first plurality of thermoelectric devices; and
the first force is greater than the second force.

3. The thermoelectric generating unit of claim 2, wherein:
a third subset of the first plurality of thermoelectric devices is disposed between the first subset of the first plurality of thermoelectric devices and the third subset of the first plurality of thermoelectric devices;
a third subset of the plurality of fasteners apply a third force to the third subset of the first plurality of thermoelectric devices; and
the third force is less than the first force and greater than the second force.

4. The thermoelectric generating unit of claim 3, wherein the first force is about 1.5 times the third force, and wherein the first force is about 3 times the second force.

5. The thermoelectric generating unit of claim 3, wherein the first force is about 11-13 kN, the third force is about 7-9 kN, and the second force is about 3-5 kN.

6. The thermoelectric generating unit of claim 2, wherein the first force is at least 1.5 times the second force.

7. The thermoelectric generating unit of claim 1, wherein each fastener comprises:
a bolt or screw; and
a spring, a Belleville washer, or a spring washer disposed along the bolt or screw.

8. The thermoelectric generating unit of claim 7, wherein a first subset of the plurality of fasteners includes a greater number of springs, Belleville washers, or spring washers disposed along the bolts or screws of that subset than does a second subset of the plurality of fasteners.

9. The thermoelectric generating unit of claim 1, wherein the first plurality of thermoelectric devices is arranged in columns and rows between the first cold-side plate and the first side of the hot-side heat exchanger, the fasteners respectively being disposed within gaps between the columns and rows.

10. The thermoelectric generating unit of claim 9, comprising four fasteners for every four thermoelectric devices of the first plurality of thermoelectric devices and for every four thermoelectric devices of the second plurality of thermoelectric devices.

11. The thermoelectric generating unit of claim 1, wherein the hot-side heat exchanger further comprises fins disposed within each of the one or more discrete channels.

12. The thermoelectric generating unit of claim 11, wherein the fins comprise stainless steel, nickel plated copper, or stainless steel clad copper.

13. The thermoelectric generating unit of claim 11, wherein a density of the fins within each of the one or more discrete channels is at least 12 fins per inch.

14. The thermoelectric generating unit of claim 1, wherein the hot-side heat exchanger includes at least one threaded rod configured to sealingly couple the hot-side heat exchanger to a pipe flange.

15. The thermoelectric generating unit of claim 1, wherein the first cold-side plate further comprises pin fins, straight fins, or offset fins.

16. The thermoelectric generating unit of claim 15, wherein the pin fins are arranged in an in-line arrangement or in a staggered arrangement.

17. The thermoelectric generating unit of claim 1, wherein the first plurality of thermoelectric devices is disposed on a circuit board.

18. The thermoelectric generating unit of claim 1, wherein the first plurality of thermoelectric devices comprise a thermoelectric material, the thermoelectric material being selected from the group consisting of: tetrahedrite, magnesium silicide, magnesium silicide stannide, silicon, silicon nanowire, bismuth telluride, skutterudite, lead telluride, TAGS (tellurium-antimony-germanium-silver), zinc antimonide, silicon germanium, and a half-Heusler compound.

19. The thermoelectric generating unit of claim 1, wherein:
at least one of the first cold-side plate and the second cold-side plate includes a high efficiency cold-side heat exchanger; and
the hot-side heat exchanger includes a high efficiency hot-side heat exchanger.

20. The thermoelectric generating unit of claim 1, wherein the first cold-side plate includes an inlet for coolant inflow and an outlet for coolant outflow, wherein the inlet and outlet are on the same side of the first cold-side plate as one another.

21. The thermoelectric generating unit of claim 1, further comprising at least one of the following:
a kapton film disposed between the first side of the hot-side heat exchanger and at least one thermoelectric device of the first plurality of thermoelectric devices;
a kapton film disposed between the first cold-side plate and at least one thermoelectric device of the first plurality of thermoelectric devices;
a mica sheet disposed between the first side of the hot-side heat exchanger and at least one thermoelectric device of the first plurality of thermoelectric devices;
a graphite sheet disposed between the first side of the hot-side heat exchanger and at least one thermoelectric device of the first plurality of thermoelectric devices;
a gap pad disposed between the first cold-side plate and at least one thermoelectric device of the first plurality of thermoelectric devices; and
an anodized layer disposed between the first cold-side plate and at least one thermoelectric device of the first plurality of thermoelectric devices.

22. A method of assembling a thermoelectric generating unit, comprising:
providing a hot-side heat exchanger including a first side, a second side, and one or more discrete channels;
providing a substantially flat first cold-side plate;
providing a substantially flat second cold-side plate;
arranging a first plurality of thermoelectric devices between the first cold-side plate and the first side of the hot-side heat exchanger;
arranging a second plurality of thermoelectric arranged between the second cold-side plate and the second side of the hot-side heat exchanger;
disposing a plurality of fasteners extending between the first cold-side plate and the second cold-side plate at respective locations outside of the one or more discrete channels of the hot-side heat exchanger and within gaps between the thermoelectric devices of the first plurality and within gaps between the thermoelectric devices of the second plurality;
compressing by the fasteners the first plurality of thermoelectric devices between the first cold-side plate and the first side of the hot-side heat exchanger and the second plurality of thermoelectric devices between the second cold-side plate and the second side of the hot-side heat exchanger.

23. The method of claim 22, further comprising:
centrally disposing a first subset of the first plurality of thermoelectric devices;
peripherally disposing a second subset of the first plurality of thermoelectric devices;
applying a first force to the first subset of the first plurality of thermoelectric devices with a first subset of the plurality of fasteners; and
applying a second force to the second subset of the first plurality of thermoelectric devices with a second subset of the plurality of fasteners;
wherein the first force is greater than the second force.

24. The method of claim 23, further comprising:
disposing a third subset of the first plurality of thermoelectric devices is between the first subset of the first plurality of thermoelectric devices and the third subset of the first plurality of thermoelectric devices; and
applying a third force to the third subset of the first plurality of thermoelectric devices with a third subset of the plurality of fasteners;
wherein the third force is less than the first force and greater than the second force.

25. The method of claim 24, wherein the first force is about 1.5 times the third force, and wherein the first force is about 3 times the second force.

26. The method of claim 24, wherein the first force is about 11-13 kN, the third force is about 7-9 kN, and the second force is about 3-5 kN.

27. The method of claim 23, wherein the first force is at least 1.5 times the second force.

28. The method of claim 22, wherein each fastener comprises:
a bolt or screw; and
a spring, a Belleville washer, or a spring washer disposed along the bolt or screw.

29. The method of claim 28, wherein a first subset of the plurality of fasteners includes a greater number of springs, Belleville washers, or spring washers disposed along the bolts or screws of that subset than does a second subset of the plurality of fasteners.

30. The method of claim 22, further comprising:
arranging the first plurality of thermoelectric devices in columns and rows between the first cold-side plate and the first side of the hot-side heat exchanger; and
respectively disposing the fasteners within gaps between the columns and rows.

31. The method of claim 30, comprising disposing four fasteners for every four thermoelectric devices.

32. The method of claim 22, wherein the hot-side heat exchanger further comprises fins disposed within each of the one or more discrete channels.

33. The method of claim 32, wherein the fins comprise stainless steel, nickel plated copper, or stainless steel clad copper.

34. The method of claim 32, wherein a density of the fins within each of the one or more discrete channels is at least 12 fins per inch.

35. The method of claim 22, wherein the hot-side heat exchanger includes at least one threaded rod, the method further comprising sealingly coupling the hot-side heat exchanger to a pipe flange via the at least one threaded rod.

36. The method of claim 22, wherein the first cold-side plate further comprises pin fins, straight fins, or offset fins.

37. The method of claim 36, wherein the pin fins are arranged in an in-line arrangement or in a staggered arrangement, or include brazed offset pin fins.

38. The method of claim 22, further comprising disposing the first plurality of thermoelectric devices on a circuit board.

39. The method of claim 22, wherein the first plurality of thermoelectric devices comprise a thermoelectric material, the thermoelectric material being selected from the group consisting of: tetrahedrite, magnesium silicide, magnesium silicide stannide, silicon, silicon nanowire, bismuth telluride, skutterudite, lead telluride, TAGS (tellurium-antimony-germanium-silver), zinc antimonide, silicon germanium, and a half-Heusler compound.

40. The method of claim 22, wherein:
at least one of the first cold-side plate and the second cold-side plate includes a high efficiency cold-side heat exchanger; and
the hot-side heat exchanger includes a high efficiency hot-side heat exchanger.

41. The method of claim 22, wherein the first cold-side plate includes an inlet for coolant inflow and an outlet for coolant outflow, wherein the inlet and outlet are on the same side of the first cold-side plate as one another.

42. The method of claim 22, further comprising at least one of the following:
disposing a kapton film between the first side of the hot-side heat exchanger and at least one thermoelectric device of the first plurality of thermoelectric devices;
disposing a kapton film between the first cold-side plate and at least one thermoelectric device of the first plurality of thermoelectric devices;
disposing a mica sheet between the first side of the hot-side heat exchanger and at least one thermoelectric device of the first plurality of thermoelectric devices;
disposing a graphite sheet between the first side of the hot-side heat exchanger and at least one thermoelectric device of the first plurality of thermoelectric devices;
disposing a gap pad between the first cold-side plate and at least one thermoelectric device of the first plurality of thermoelectric devices; and
disposing an anodized layer between the first cold-side plate and at least one thermoelectric device of the first plurality of thermoelectric devices.
